(19) United States
(12) Patent Application Publication
(10) Pub. No.: US 2023/0144542 A1
(43) Pub. Date: May 11, 2023

(54) MANUFACTURING METHOD OF SEMICONDUCTOR DEVICE AND SEMICONDUCTOR DEVICE

(71) Applicant: FUJI ELECTRIC CO., LTD., Kanagawa (JP)

(72) Inventors: Norihiro KOMIYAMA, Matsumoto-city (JP); Seiji NOGUCHI, Matsumoto-city (JP); Yoshihiro IKURA, Matsumoto-city (JP); Yosuke SAKURAI, Azumino-city (JP); Yuichi HARADA, Matsumoto-city (JP)

(21) Appl. No.: 17/972,527

(22) Filed: Oct. 24, 2022

Related U.S. Application Data
(63) Continuation of application No. PCT/JP2021/021995, filed on Jun. 9, 2021.

(30) Foreign Application Priority Data
Nov. 17, 2020 (JP) 2020-190961

(51) Int. Cl. H01L 29/739; H01L 29/66; H01L 21/265

(52) U.S. Cl. CPC H01L 29/7397; H01L 29/66348; H01L 21/26513

(57) ABSTRACT

Provided is a manufacturing method of a semiconductor device, the manufacturing method including implanting a first dopant of a first conductivity type from an implantation surface of a semiconductor substrate into a first implantation position and implanting a second dopant of the first conductivity type from the implantation surface of the semiconductor substrate into a second implantation position having a larger distance from the implantation surface than the first implantation position after implanting the first dopant. The first implantation position and the second implantation position may be arranged in the buffer region.

The contents of the following Japanese patent application(s) are incorporated herein by reference:

NO. 2020-190961 filed in JP on Nov. 17, 2020

NO. PCT/JP2021/021995 filed in WO on Jun. 9, 2021

### BACKGROUND

### 1. Technical Field

The present invention relates to a manufacturing method of a semiconductor device and a semiconductor device.

### 2. Related Art

Conventionally, as a field stopper layer of a semiconductor device, a configuration including a plurality of impurity concentration peaks is known (see, for example, Patent Document 1).
Patent Document 1: WO 2013/89256

### BRIEF DESCRIPTION OF THE DRAWINGS

FIG. 1 illustrates a top view showing an example of a semiconductor device 100.

FIG. 2 illustrates an enlarged view of a region D in FIG. 1.

FIG. 3 illustrates a view showing an example of a cross section e-e in FIG. 2.

FIG. 4A illustrates a view showing an example of a doping concentration distribution, a hydrogen chemical concentration distribution, a helium chemical concentration distribution, and a recombination center concentration distribution taken along line F-F in FIG. 3.

FIG. 4B illustrates a view showing a relationship between an implantation depth (Rp) of ions and acceleration energy required for implantation.

FIG. 4C illustrates a view showing a relationship between the implantation depth (Rp) of ions and a straggling (ΔRp, standard deviation) in an implantation direction.

FIG. 5A illustrates a view showing an example of a doping concentration distribution, a hydrogen chemical concentration distribution, a helium chemical concentration distribution, and a recombination center concentration distribution in the buffer region 20.

FIG. 5B illustrates a view showing an example of the doping concentration distribution, the hydrogen chemical concentration distribution, the helium chemical concentration distribution, and the recombination center concentration distribution in the buffer region 20.

FIG. 6 illustrates a view showing another example of the helium chemical concentration distribution and the recombination center concentration distribution in the buffer region 20.

FIG. 7 illustrates a view showing still another example of the helium chemical concentration distribution and the recombination center concentration distribution in the buffer region 20.

FIG. 8 illustrates a view showing still another example of the helium chemical concentration distribution and the recombination center concentration distribution in the buffer region 20.

FIG. 9 illustrates a view showing still another example of the helium chemical concentration distribution and the recombination center concentration distribution in the buffer region 20.

FIG. 10A illustrates a view showing still another example of the helium chemical concentration distribution and the recombination center concentration distribution in the buffer region 20.

FIG. 10(B illustrates a view showing still another example of the helium chemical concentration distribution and the recombination center concentration distribution in the buffer region 20.

FIG. 10C illustrates a view showing still another example of the helium chemical concentration distribution and the recombination center concentration distribution in the buffer region 20.

FIG. 11 illustrates a full width at half maximum Wk of a helium chemical concentration peak 221.

FIG. 12A illustrates a view showing an example of the doping concentration distribution and the hydrogen chemical concentration distribution in the buffer region 20.

FIG. 12B illustrates a view showing some processes in a manufacturing method of the semiconductor device 100.

FIG. 12C illustrates a view showing another example of the doping concentration distribution and the hydrogen chemical concentration distribution in the buffer region 20.

FIG. 12D illustrates a view showing still another example of the doping concentration distribution and the hydrogen chemical concentration distribution in the buffer region 20.

FIG. 12E illustrates a view showing still another example of the doping concentration distribution and the hydrogen chemical concentration distribution in the buffer region 20.

FIG. 12F illustrates a view showing another example of the processes in the manufacturing method of the semiconductor device 100.

FIG. 12G illustrates a view showing still another example of the processes in the manufacturing method of the semiconductor device 100.

FIG. 13 shows an example of a carrier concentration distribution and a helium chemical concentration distribution in the buffer region 20 of a comparative example.

FIG. 14 illustrates a view showing another example of the cross section e-e.

FIG. 15 illustrates a view showing an example of a doping concentration distribution and a hydrogen chemical concentration distribution taken along line F-F in FIG. 14.

FIG. 16 illustrates a view showing an example of a method of forming the buffer region 20.

FIG. 17 illustrates a view showing a cross-sectional shape of a collector region 22 according to the comparative example.

FIG. 18 illustrates a view showing a result of a breakdown voltage test of a semiconductor device.

FIG. 19 illustrates a view showing a result of a breakdown voltage test of the semiconductor device.

FIG. 20 illustrates a view showing another example of the semiconductor device 100.

FIG. 21 illustrates a view showing another example of the manufacturing process of the semiconductor device 100.

FIG. 22 illustrates a view showing an example of a doping concentration distribution and a hydrogen chemical concentration distribution of the semiconductor device 100 shown in FIG. 21.

FIG. 23 illustrates a view showing still another example of the cross section e-e.

FIG. 24 illustrates a view showing an example of a method of forming the buffer region 20 shown in FIG. 23.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

Further, a region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor.

In the semiconductor substrate of the present specification, bulk donors of the N type are distributed throughout. The bulk donor is a dopant donor substantially uniformly contained in an ingot during the manufacture of the ingot from which the semiconductor substrate is made. The bulk donor of this example is an element other than hydrogen. The bulk donor dopant is, for example, phosphorous, antimony, arsenic, selenium, or sulfur, but the invention is not limited to these. The bulk donor of this example is phosphorous. The bulk donor is also contained in a P type region. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. Further, as the semiconductor substrate, a non-doped substrate not containing a dopant such as phosphorous may be used. In that case, the bulk donor concentration (D0) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type. In the specification, a unit system is the SI base unit system unless otherwise particularly noted. Although a unit of length is represented using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by voltage-capacitance profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

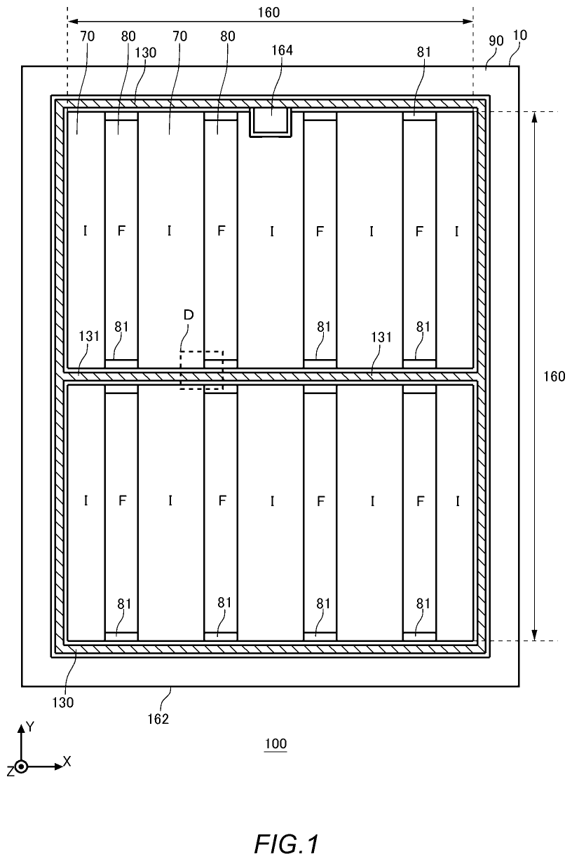

FIG. 1 illustrates a top view showing an example of a semiconductor device 100. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1.

The active portion 160 is provided with at least one of a transistor portion 70 including a transistor element such as an IGBT, and a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10, and the semiconductor device 100 is a reverse conduction type IGBT (RC-IGBT). The active portion 160 in another example may be provided with only one of the transistor portion 70 and the diode portion 80.

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of P+ type may be provided in a region other than the cathode region. In the specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example has an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. Further, the outer circumferential gate runner 130 is connected to the gate pad 164. The outer circumferential gate runner 130 is arranged above the semiconductor substrate 10. The outer circumferential gate runner 130 may be a metal wiring including aluminum.

The active-side gate runner 131 is provided in the active portion 160. Providing the active-side gate runner 131 in the active portion 160 can reduce a variation in wiring length from the gate pad 164 for each region of the semiconductor substrate 10.

The active-side gate runner 131 is connected to the gate trench portion of the active portion 160. The active-side gate runner 131 is arranged above the semiconductor substrate 10. The active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 substantially at the center of the Y axis direction, the outer circumferential gate runner 130 enclosing the active portion 160. When the active portion 160 is divided by the active-side gate runner 131, the transistor portion 70 and the diode portion 80 may be alternately arranged in the X axis direction in each divided region.

Further, the semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

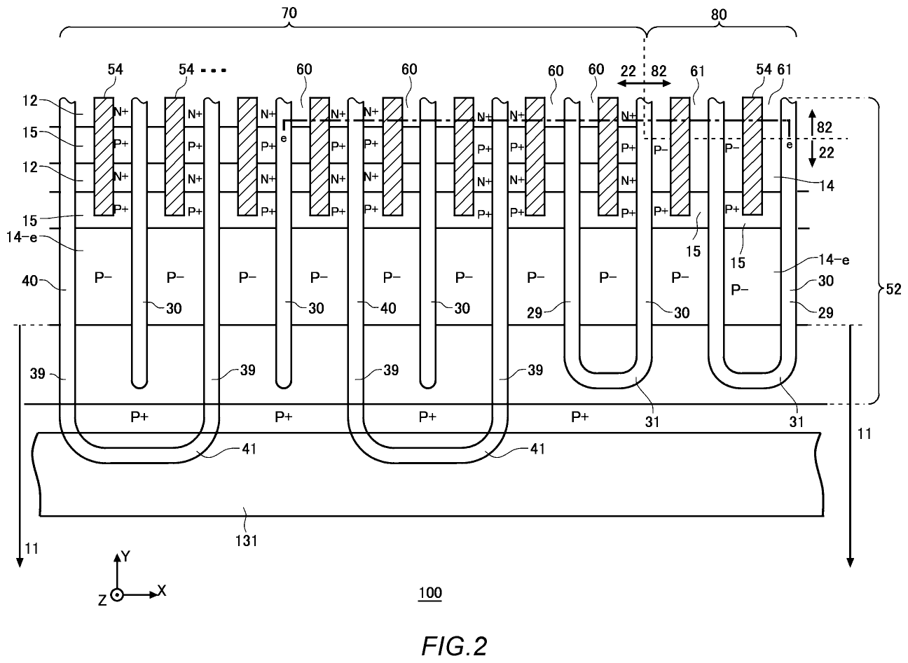

FIG. 2 illustrates an enlarged view of a region D in FIG. 1. The region D is a region including the transistor portion 70, the diode portion 80, and the active-side gate runner 131. The semiconductor device 100 of this example includes a gate trench portion 40, a dummy trench portion 30, a well region 11, an emitter region 12, a base region 14, and a contact region 15 which are provided inside the upper surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the upper surface of the semiconductor substrate 10. The emitter electrode 52 and the active-side gate runner 131 are provided in isolation each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided on the upper side of the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 of this example is provided away from an end of the contact hole 54 in the Y axis direction toward the active-side gate runner 131 side. The well region 11 is a second conductivity type region in which the doping concentration is higher than the base region 14. The base region 14 of this example is a P− type, and the well region 11 is a P+ type.

Each of the transistor portion 70 and the diode portion 80 includes a plurality of trench portions arranged in the array direction. In the transistor portion 70 of this example, one or more gate trench portions 40 and one or more dummy trench portions 30 are alternately provided along the array direction. In the diode portion 80 of this example, the plurality of dummy trench portions 30 are provided along the array direction. In the diode portion 80 of this example, the gate trench portion 40 is not provided.

The gate trench portion 40 of this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is desirably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench, on the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged closest to the active-side gate runner 131, in the base region 14 exposed on the upper surface of the semiconductor substrate 10, is to be a base region 14-e. While FIG. 2 shows the base region 14-e arranged at one end portion of each mesa portion in the extending direction, the base region 14-e is also arranged at the other end portion of each mesa portion. Each mesa portion may be provided with at least one of a first conductivity type of emitter region 12, and a second conductivity type of contact region 15 in a region sandwiched between the base regions 14-e in the top view. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 in the mesa portion 60 are alternately arranged along the extending direction of the trench portion (the Y axis direction).

In another example, the contact region 15 and the emitter region 12 in the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged away from the well region 11 in the Y axis direction. With this configuration, the distance between the P type region (the well region 11) having a relatively high doping concentration and formed up to the deep position, and the cathode region 82 is ensured, so that the breakdown voltage can be improved. The end portion in the Y axis direction of the cathode region 82 of this example is arranged farther away from the well region 11 than the end portion in the Y axis direction of the contact hole 54. In another example, the end portion in the Y axis direction of the cathode region 82 may be arranged between the well region 11 and the contact hole 54.

### First Example

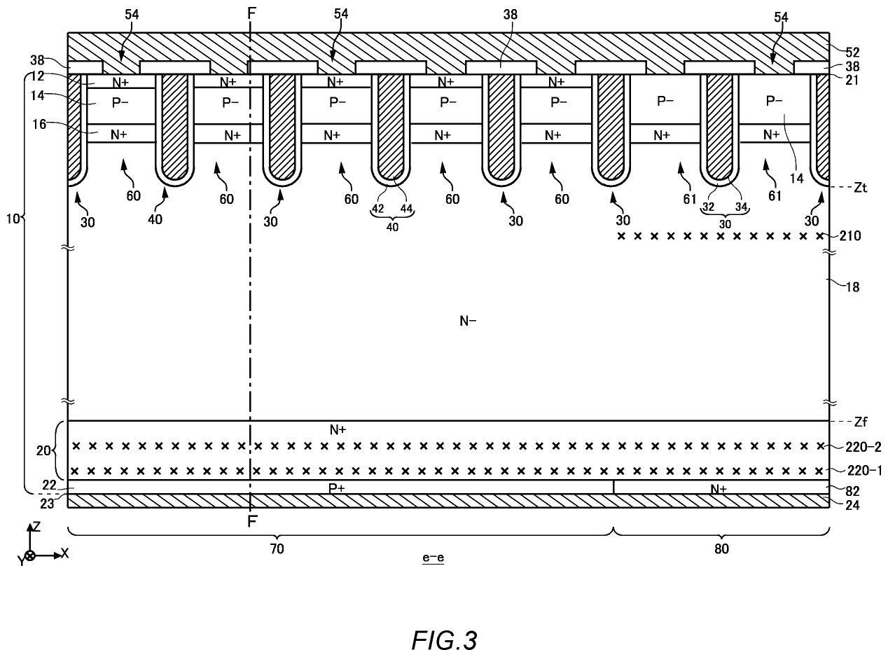

FIG. 3 illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with the contact hole 54 described in FIG. 2.

The emitter electrode 52 is provided on the upper side of the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the specification, the direction in which the emitter electrode 52 is connected to the collector electrode 24 (the Z axis direction) is referred to as a depth direction.

The semiconductor substrate 10 includes an N type or N+ type of drift region 18. The drift region 18 is provided in each of the transistor portion 70 and the diode portion 80.

In the mesa portion 60 of the transistor portion 70, an N+ type of emitter region 12 and a P− type of base region 14 are provided in order from an upper surface 21 side of the semiconductor substrate 10. The drift region 18 is provided below the base region 14. The mesa portion 60 may be provided with an N+ type of accumulation region 16. The accumulation region 16 is arranged between the base region 14 and the drift region 18.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is an N+ type region with a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

The mesa portion 61 of the diode portion 80 is provided with the P− type of base region 14 in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, an N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak indicates a doping concentration at the local maximum of the concentration peak. Further, as the doping concentration of the drift region 18, an average value of doping concentrations in the region where the doping concentration distribution is substantially flat may be used.

The buffer region 20 may have two or more concentration peaks in the depth direction (Z axis direction) of the semiconductor substrate 10. The concentration peak of the buffer region 20 may be provided at the same depth position as, for example, a chemical concentration peak of hydrogen (proton) or phosphorous. The buffer region 20 may function as a field stopper layer which prevents a depletion layer expanding from the lower end of the base region 14 from reaching the collector region of the P+ type 22 and the cathode region 82 of the N+ type. In the present specification, a depth position of an upper end of the buffer region 20 is set as Zf. The depth position Zf may be a position at which the doping concentration is higher than the doping concentration of the drift region 18.

In the transistor portion 70, the collector region of the P+ type 22 is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the above described example. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and reaches the drift region 18. In a region where at least any one of the emitter region 12, the contact region 15, and the accumulation region 16 is provided, each trench portion also passes through the doping regions of these to reach the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

As described above, the transistor portion 70 is provided with the gate trench portion 40 and the dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 of this example are covered with the interlayer dielectric film 38 on the upper surface 21 of the semiconductor substrate 10. It is noted that the bottoms of the dummy trench portion 30 and the gate trench portion 40 may be formed in a curved-surface shape (a curved-line shape in the cross section) convexly downward. In the present specification, a depth position of a lower end of the gate trench portion 40 is set as Zt.

An upper-surface-side lifetime killer 210 may be provided on the upper surface 21 side of the semiconductor substrate 10. The upper-surface-side lifetime killer 210 is a recombination center of a lattice defect or the like locally formed in the depth direction. In each drawing, the peak position of the density distribution of the lifetime killer in the depth direction is schematically indicated by an X mark. In the present specification, the peak position will be described as the position of the lifetime killer. The X marks are discretely arranged in the X axis direction, but the lifetime killer is uniformly provided in the X axis direction unless otherwise described.

The upper-surface-side lifetime killer 210 can be formed by implanting particles such as helium into a predetermined depth position from the upper surface 21 of the semiconductor substrate 10. A concentration peak of particles such as helium may be arranged at the same depth position as that of the upper-surface-side lifetime killer 210. The upper-surface-side lifetime killer 210 may be arranged below each trench portion. Further, the upper-surface-side lifetime killer 210 is preferably provided at a position not overlapping the gate trench portion 40 in the top view. With this configuration, the upper-surface-side lifetime killer 210 can be formed by implanting particles such as helium without damaging the gate dielectric film 42. The upper-surface-side lifetime killer 210 of this example is provided over the entire diode portion 80 in the top view. The upper-surface-side lifetime killer 210 in FIG. 3 is not provided in the transistor portion 70, but in another example, the upper-surface-side lifetime killer 210 may be provided in a part of a region of the transistor portion 70.

A lower-surface-side lifetime killer 220 is provided on the lower surface 23 side of the semiconductor substrate 10. The lower-surface-side lifetime killer 220 may be formed by implanting particles such as helium from the lower surface 23 side of the semiconductor substrate 10. A plurality of the lower-surface-side lifetime killers 220 may be arranged at different positions in the depth direction. In the example of FIG. 3, a first lower-surface-side lifetime killer 220-1 and a second lower-surface-side lifetime killer 220-2 are arranged at different depth positions. However, the lower-surface-side lifetime killers 220 may be provided at three or more depth positions. A peak of a helium chemical concentration may be provided at the same depth position as that of each of the lower-surface-side lifetime killers 220.

In the buffer region 20, two or more lower-surface-side lifetime killers 220 may be provided. This makes it easy to control the distribution of the lifetime killer in the buffer region 20. Therefore, the carrier lifetime can be controlled precisely.

The lower-surface-side lifetime killer 220 may be provided over the entire diode portion 80 in the top view. Further, the lower-surface-side lifetime killer 220 may be provided over the entire transistor portion 70 in the top view. The lower-surface-side lifetime killer 220 may be provided over the entire active portion 160 in the top view, or may be provided over the entire semiconductor substrate 10 in the top view. The first lower-surface-side lifetime killer 220-1 and the second lower-surface-side lifetime killer 220-2 may be provided in the same range in the top view.

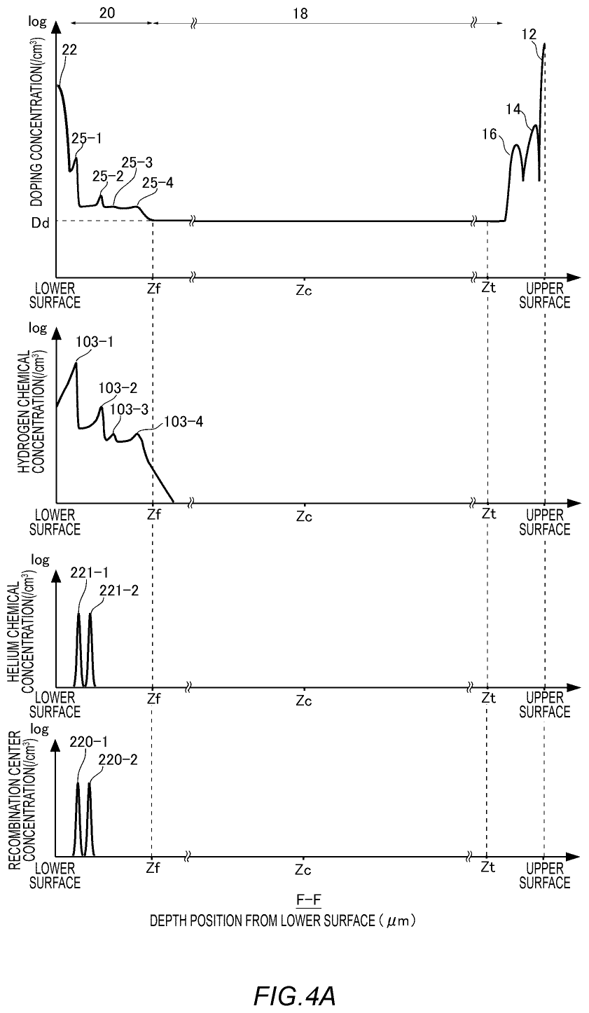

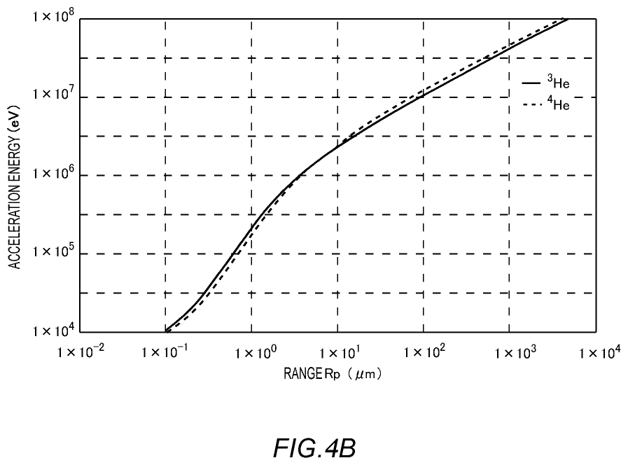

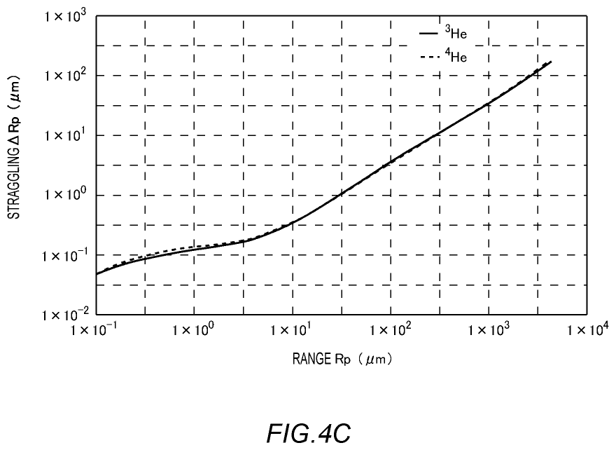

FIG. 4A illustrates a view showing an example of a doping concentration distribution, a hydrogen chemical concentration distribution, a helium chemical concentration distribution, and a recombination center concentration distribution taken along line F-F in FIG. 3. In FIG. 4A, the center position in the depth direction of the semiconductor substrate 10 is set as Zc. That is, the region on the upper surface 21 side of the semiconductor substrate 10 is a region between the upper surface 21 and the center position Zc, and the region on the lower surface 23 side is a region between the lower surface 23 and the center position Zc.

The emitter region 12 contains an N type dopant such as phosphorous. The base region 14 contains a P type dopant such as boron. The accumulation region 16 contains an N type dopant such as phosphorous or hydrogen. The doping concentration distribution may have respective concentration peaks in the emitter region 12, the base region 14, and the accumulation region 16.

The drift region 18 is a region having a substantially flat doping concentration. A doping concentration Dd of the drift region 18 may be the same as the bulk donor concentration of the semiconductor substrate 10, or may be higher than the bulk donor concentration.

The buffer region 20 of this example has a plurality of doping concentration peaks 25-1, 25-2, 25-3, and 25-4 in the doping concentration distribution. Each doping concentration peak 25 may be formed by locally implanting hydrogen ions. In another example, each doping concentration peak 25 may be formed by implanting an N type dopant such as phosphorous. The collector region 22 contains a P type dopant such as boron. Further, the cathode region 82 shown in FIG. 3 contains an N type dopant such as phosphorous.

The hydrogen chemical concentration distribution of this example has a plurality of local hydrogen chemical concentration peaks 103 in the buffer region 20. By implanting hydrogen ions into the buffer region 20, a VOH defect in which hydrogen, lattice defects, and oxygen are combined is formed and functions as a donor. The hydrogen chemical concentration peak 103 of this example is provided at the same depth position as that of the doping concentration peak 25. Providing two peaks at the same depth position means that the local maximum of one peak is arranged within a range of the full width at half maximum of the other peak. When the concentration of the hydrogen chemical concentration peak 103 is not sufficiently high, a clear doping concentration peak 25 may not be observed at the same depth position as that of the hydrogen chemical concentration peak 103. The hydrogen chemical concentration of this example steeply decreases immediately after entering the drift region 18 from the buffer region 20. Thus, VOH defects are hardly formed in the drift region 18. In another example, hydrogen may diffuse into the drift region 18 to form VOH defects. In this case, the doping concentration of the drift region 18 is higher than the bulk donor concentration.

The buffer region 20 has two or more helium chemical concentration peaks 221 arranged at different positions in the depth direction of the semiconductor substrate 10. In this example, a first helium chemical concentration peak 221-1 and a second helium chemical concentration peak 221-2 are provided in the buffer region 20. The second helium chemical concentration peak 221-2 is arranged farther away from the lower surface 23 than the first helium chemical concentration peak 221-1.

As described above, the lower-surface-side lifetime killer 220 is formed in the vicinity of each helium chemical concentration peak 221. The lower-surface-side lifetime killer 220 may be a recombination center that promotes carrier recombination. The recombination center may be a lattice defect. The lattice defects may be mainly composed of vacancies such as monatomic vacancies (V) and diatomic vacancies or divacancies (VV), may be dislocations, may be interstitial atoms, or may be transition metals or the like. For example, atoms adjacent to the vacancies have dangling bonds. In a broad sense, the lattice defects may also include donors and acceptors. However, in the present specification, the lattice defects mainly composed of vacancies may be referred to as vacancy-type lattice defects, vacancy-type defects, or simply lattice defects. In the present specification, the lattice defect may be simply referred to as a recombination center or a lifetime killer as a recombination center contributing to the carrier recombination. The lifetime killer may be formed by implanting helium ions into the semiconductor substrate 10. Since the lifetime killer formed by implanting helium may be terminated by hydrogen existing in the buffer region 20, the depth position of the density peak of the lifetime killer may not be identical to the depth position of the helium chemical concentration peak 221.

By implanting helium into two or more depth positions of the buffer region 20, the density distribution of the lower-surface-side lifetime killer 220 in the buffer region 20 can be easily controlled. ³He or ⁴He may be implanted into each depth position. ³He is a helium isotope including two protons and one neutron. ⁴He is a helium isotope including two protons and two neutrons.

When ³He or ⁴He is implanted, without passing through a buffer material (aluminum or the like), with the smallest acceleration energy at which the implantation depth is uniquely determined, a half-value width in the depth direction of the concentration peak of the helium chemical concentration can be reduced.

FIG. 4B illustrates a view showing a relationship between an implantation depth (Rp) of ions and acceleration energy required for implantation. In this example, helium ions are directly implanted into the silicon semiconductor substrate 10 without passing through the buffer material. In FIG. 4B, a horizontal axis represents a range Rp(μm), and a vertical axis represents the acceleration energy E(eV) required for implantation. In FIG. 4B, an example of ³He is indicated by a solid line, and an example of ⁴He is indicated by a broken line.

log₁₀(Rp) is set as x, and log₁₀(E) is set as y.

In ³He, a relationship between the range Rp and an acceleration energy E may be given by Equation (1).

y=4.52505E−03x⁶−4.71471E−02x⁵+1.67185E−01x⁴−1.72038E−01x³−2.92723E−01x²+1.39782E+00×+5.33858E+00 Equation (1)

Note that E−A is 10^{-A}, and E+A is 10^{A}.

The acceleration energy calculated by substituting an actual range Rp′ at the time of manufacturing the semiconductor device 100 into Equation (1) is set as E. When an actual acceleration energy E′ at the time of manufacture is within ±20% of the acceleration energy E calculated from Equation (1), it may be considered that ³He is used.

In ⁴He, the relationship between the range Rp and the acceleration energy E may be given by Equation (2).

y=2.90157E−03x⁶−3.66593E−02x⁵+1.59363E−01x⁴−2.31938E−01x³−2.00999E−01x²+1.45891E+00×+5.27160E+00 Equation (2)

When the actual acceleration energy E′ at the time of manufacture is within ±20% of the acceleration energy E calculated from Equation (2) using the actual range Rp′, it may be considered that ⁴He is used.

As illustrated in FIG. 4B, when the range Rp is equal to or larger than a boundary value with a value of a region where the range Rp is 8 μm to 10 μm set as the boundary value, the acceleration energy of ⁴He is higher by approximately 10% than the acceleration energy of ³He. When the range Rp is equal to or less than the boundary value, the acceleration energy of ³He is higher by approximately 10% than the acceleration energy of ⁴He. This is presumed to be due to changes in a balance between an electronic stopping power and a nuclear stopping power depending on the number of neutrons of the isotope. As an example, when the range Rp is 10 μm or less, ⁴He may be used. Accordingly, helium ions can be implanted with approximately 10% lower acceleration energy. When the range Rp is larger than 10 μm, ³He may be used.

FIG. 4C illustrates a view showing a relationship between the implantation depth (Rp) of ions and a straggling (ΔRp, standard deviation) in an implantation direction. The implantation direction in this example is the depth direction of the semiconductor substrate 10. Also in this example, helium ions are directly implanted into the silicon semiconductor substrate 10 without passing through the buffer material. In FIG. 4C, a horizontal axis represents the range Rp (μm), and a vertical axis represents the straggling ΔRp (μm). In FIG. 4C, an example of ³He is indicated by a solid line, and an example of ⁴He is indicated by a broken line.

The straggling ΔRp may be calculated assuming that the helium concentration distribution is a Gaussian distribution. For example, the straggling ΔRp may be a distance (distribution width) between two points having a concentration of 0.60653 times the concentration peak value, or may be a distance between two points having a concentration of 0.6 times the concentration peak value. When a local minimum value or the like between adjacent concentration peaks is larger than 0.6 times the concentration peak value, a distance between inflection points such as the local minimum value of the concentration distribution may be used as the straggling ΔRp.

log₁₀(Rp) is set as x, and log₁₀(ΔRp) is set as y.

In ³He, the relationship between the range Rp and the straggling ΔRp may be given by Equation (3).

y=5.00395E−04x⁶+9.91651E−03x⁵−9.76015E−02x⁴+2.12587E−01x³+1.30994E−01x²+2.25458E−01×−8.59463E−01 Equation (3)

The straggling calculated by substituting the actual range Rp′ at the time of manufacturing the semiconductor device 100 into Equation (3) is set as ΔRp. When the actual straggling ΔRp′ at the time of manufacture is within ±20% of the straggling ΔRp calculated from Equation (3), it may be considered that ³He is used. The actual straggling ΔRp′ preferably does not include helium diffusion due to thermal annealing. The actual straggling ΔRp′ may be a value measured after helium implantation and before thermal annealing, or may be a value obtained by subtracting the helium diffusion from the value measured after the thermal annealing.

In ⁴He, the relationship between the range Rp and the straggling ΔRp may be given by Equation (4).

y=3.10234E−03x⁶−9.20762E−03x⁵−6.13612E−02x⁴+2.34304E−01x³+3.88591E−02x²+2.22955E−01×−8.01967E−01 Equation (4)

When the actual straggling ΔRp′ at the time of manufacture is within ±20% of the straggling ΔRp calculated from Equation (4) using the actual range Rp′, it may be considered that ⁴He is used. The actual straggling ΔRp′ preferably does not include helium diffusion due to thermal annealing.

As illustrated in FIG. 4C, when the range Rp is equal to or less than a boundary value with a value of a region where the range Rp is 10 to 20 μm set as the boundary value, the straggling ΔRp of ³He is smaller by approximately 10% than the straggling ΔRp of ⁴He. When the range Rp is equal to or larger than the boundary value, the stragglings ΔRp are substantially equal between ³He and ⁴He. This is presumed to be due to changes in a balance between an electronic stopping power and a nuclear stopping power depending on the number of neutrons of the isotope.

As an example, when the range Rp is 20 μm or less, ³He may be used. Accordingly, the straggling ΔRp can be made approximately 10% smaller. Alternatively, in a case where a difference which is given to the helium chemical concentration distribution or electrical characteristics by the difference of approximately 10% in the straggling ΔRp is sufficiently small, even when the range Rp is 20 μm or less, it may be considered that the stragglings ΔRp are substantially equal between ³He and ⁴He. In this case, helium atoms implanted into the semiconductor substrate 10 may be ³He or may be ⁴He.

As an example, the full width at half maximum of the helium chemical concentration peak 221 when ⁴He is implanted is 1 μm or less. The full width at half maximum of the helium chemical concentration peak 221 may be 0.5 μm or less. By arranging a plurality of helium chemical concentration peaks 221 having a small half-value width in the buffer region 20, the distribution shape of the lower-surface-side lifetime killer 220 can be easily controlled. Further, it is possible to suppress VOH defects formed by helium implantation from being distributed in a wide range. Thus, the doping concentration distribution of the buffer region 20 can be suppressed from varying in a wide range.

Further, by providing the plurality of helium chemical concentration peaks 221, the total concentration of the lower-surface-side lifetime killer 220 can be maintained high. Thus, the lifetime of the carrier can be shortened at the time of turning off the semiconductor device 100 or the like, and a tail current can be suppressed.

When the acceleration energy E of ³He is He approximately 20 MeV or more (the range Rp is 270 μm or more), the straggling ΔRp is 10 μm or more. When the acceleration energy E of ⁴He is approximately 21 MeV or more (the range Rp is 250 μm or more), the straggling ΔRp is 10 μm or more. In this case, the full width at half maximum of the helium chemical concentration peak 221 cannot be made sufficiently smaller than the width of the buffer region 20 in the depth direction. Thus, VOH defects are formed in a wide range of the buffer region 20, and the doping concentration distribution is varied. Thus, an electric field may be locally concentrated in the buffer region 20, so that a short-circuit current tolerance decreases. In contrast, by reducing the half-value width of the helium chemical concentration peak 221, the short-circuit current tolerance can be easily maintained. Therefore, in the case of implanting either ³He or ⁴He, the acceleration energy E may be 20 MeV or less, or may be 10 MeV or less. Alternatively, the acceleration energy E of at least one or more or two or more helium chemical concentration peaks 221 of the plurality of helium chemical concentration peaks 221 may be equal to or less than 10 MeV, or may be equal to or less than 5 MeV.

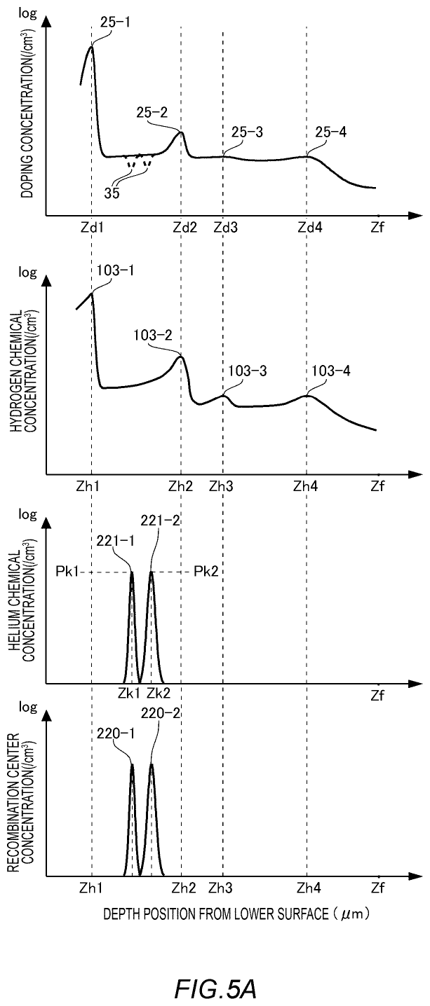

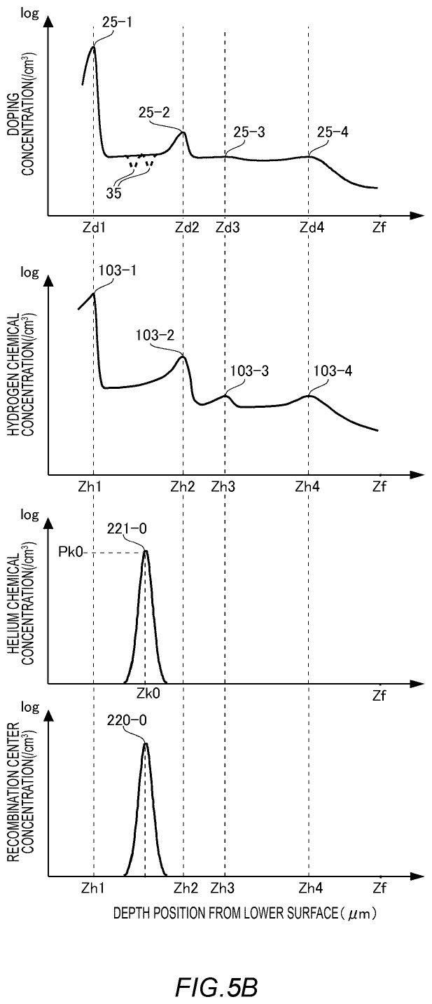

FIG. 5A illustrates a view showing an example of the doping concentration distribution, the hydrogen chemical concentration distribution, the helium chemical concentration distribution, and the recombination center concentration distribution in the buffer region 20. The concentration distributions may be similar to respective concentration distributions described in FIG. 4A.

The doping concentration distribution of this example has the doping concentration peaks 25-1, 25-2, 25-3, and 25-4 in order from the lower surface 23 side of the semiconductor substrate 10. The doping concentration peak 25-4 is an example of the deepest doping concentration peak that is arranged farthest away from the lower surface 23. The depth positions of the respective doping concentration peaks 25 are set as Zd1, Zd2, Zd3, and Zd4 in order from the lower surface 23 side. Each depth position Zd indicates a distance from the lower surface 23. Note that any doping concentration peak 25 may not be a clear peak. For example, an inflection point (kink) of the slope of the doping concentration distribution may be set as the doping concentration peak 25. The doping concentration peak 25-1 may be the doping concentration peak 25 having the largest concentration value. The doping concentration peak 25-2 may be the doping concentration peak 25 having the second largest concentration value. The doping concentration peak 25-3 may be the doping concentration peak 25 having the smallest concentration value. The doping concentration peak 25-4 may be the doping concentration peak 25 having a higher concentration than the doping concentration peak 25-3.

The hydrogen chemical concentration distribution of this example has hydrogen chemical concentration peaks 103-1, 103-2, 103-3, and 103-4 in order from the lower surface 23 side of the semiconductor substrate 10. The depth positions of the respective hydrogen chemical concentration peaks 103 are set as Zh1, Zh2, Zh3, and Zh4 in order from the lower surface 23 side. Each depth position Zh indicates a distance from the lower surface 23. A depth position Zdk may be the same position as a depth position Zhk. k is an integer of 1 to 4. The hydrogen chemical concentration peak 103-1 may be the hydrogen chemical concentration peak 103 having the largest concentration value. The hydrogen chemical concentration peak 103-2 may be hydrogen chemical concentration peak 103 having the second largest concentration value. The hydrogen chemical concentration peak 103-3 may be the hydrogen chemical concentration peak 103 having the smallest concentration value. The hydrogen chemical concentration peak 103-4 may be the hydrogen chemical concentration peak 103 having a higher concentration than the hydrogen chemical concentration peak 103-3.

The helium chemical concentration distribution of this example has the first helium chemical concentration peak 221-1 and the second helium chemical concentration peak 221-2 in order from the lower surface 23 side of the semiconductor substrate 10. The depth positions of the respective helium chemical concentration peaks 221 are set as Zk1 and Zk2 in order from the lower surface 23 side. Each depth position Zk indicates a distance from the lower surface 23. Further, the concentration values of the respective helium chemical concentration peaks 221 are set as Pk1 and Pk2 in order from the lower surface 23 side.

Two or more helium chemical concentration peaks 221 are arranged between the doping concentration peak 25-4, which is the deepest doping concentration peak, and the lower surface 23 of the semiconductor substrate 10. At least one helium chemical concentration peak 221 may be arranged between the depth positions Zd1 and Zd2. In this example, all helium chemical concentration peaks 221 are arranged between the depth positions Zd1 and Zd2. The full width at half maximum of the helium chemical concentration peak 221-2 may be larger than the full width at half maximum of the helium chemical concentration peak 221-1. The full width at half maximum of the helium chemical concentration peak 221-1 may be different from the full width at half maximum of the helium chemical concentration peak 221-2 depending on a difference in acceleration energy. In this example, a plurality of lower-surface-side lifetime killers 220 can be arranged in the vicinity of the collector region 22.

FIG. 5B illustrates a view showing an example of the doping concentration distribution, the hydrogen chemical concentration distribution, the helium chemical concentration distribution, and the recombination center concentration distribution in the buffer region 20. In this example, the helium chemical concentration distribution and the recombination center concentration distribution are different from those in the example of FIG. 5A. Other distributions may be similar to those of the example of FIG. 5A.

The buffer region 20 of this example has one helium chemical concentration peak 221-0 and one lower-surface-side lifetime killer 220-0. The position of the helium chemical concentration peak 221-0 in the depth direction is set as Zk0, and the concentration is set as Pk0.

The depth position Zk0 of the helium chemical concentration peak 221-0 is arranged between the depth positions Zk1 and Zk2. A recombination center concentration peak (lower-surface-side lifetime killer 220-0) is arranged in the vicinity of the depth position Zk0. Further, the concentration Pk0 of the helium chemical concentration peak 221-0 may be higher than any of Pk1 and Pk2. The lower-surface-side lifetime killer 220-0 may also be higher in concentration than any of the lower-surface-side lifetime killers 220-1 and 220-2.

In the example of FIGS. 5A and 5B, when the depletion layer expanding from the lower end of the base region 14 reaches the lower-surface-side lifetime killer 220 at the time of turn-off or the like, the recombination center functions as the generation center of the carrier. With this configuration, a leakage current may increase, the heat generation of the semiconductor device may be promoted, the temperature of the semiconductor device may increase, and the tolerance of turn-off or the like may decrease. As in the example of FIG. 5A, the peak concentration of the helium chemical concentration (recombination center concentration) can be decreased by arranging the plurality of lower-surface-side lifetime killers 220. With this configuration, the concentration of the generation center of the carrier can also be decreased, the leakage current can be reduced, the temperature rise of the semiconductor device can also be suppressed, and the tolerance of turn-off or the like can be increased. Further, the implantation of hole carriers from the collector region 22 into the drift region 18 can be suppressed.

Further, in the example of FIG. 5A, a distance (Zk2−Zk1) between the first helium chemical concentration peak 221-1 closest to the depth position Zd1 and the second helium chemical concentration peak 221-2 closest to the depth position Zd2 may be half or more of the distance (Zd2−Zd1). With this configuration, the plurality of lower-surface-side lifetime killers 220 can be arranged over a certain range. Further, an interval (Zk2−Zk1 in this example) between the adjacent helium chemical concentration peaks 221 in the depth direction may be 2 μm or more, may be 3 μm or more, may be 4 μm or more, or may be 5 μm or more.

The concentration values Pk of the helium chemical concentration peaks 221 may be the same. In another example, any of the concentration values Pk may be different from the other concentration values Pk. The implantation dose amount of helium ions corresponding to each helium chemical concentration peak 221 may be 1×10¹¹ (/cm²) or more, may be 3×10¹¹ (/cm²) or more, or may be 1×10¹² (/cm²) or more. The implantation dose amount of helium ions corresponding to each helium chemical concentration peak 221 may be 1×10¹³ (/cm²) or less, may be 3×10¹² (/cm²) or less, or may be 1×10¹² (/cm²) or less.

Each helium chemical concentration peak 221 may be arranged at a depth position different from that of any hydrogen chemical concentration peak 103. That is, the depth position Zk of the local maximum of each helium chemical concentration peak 221 does not fall within a range of the full width at half maximum of any hydrogen chemical concentration peak 103. With this configuration, the lifetime killer formed by helium implantation is suppressed from being terminated by hydrogen, and the concentration of the lower-surface-side lifetime killer 220 is easily maintained.

In each helium chemical concentration peak 221, the concentration value Pk may increase as a distance from the depth position Zh of the hydrogen chemical concentration peak 103 increases. With this configuration, it is possible to suppress the lifetime killer formed by helium implantation from forming VOH defects, and it is possible to suppress the variation in the shape of the doping concentration distribution in the buffer region 20.

When the carrier concentration distribution measured by the SRP method is a doping concentration distribution, the doping concentration distribution may have a valley portion 35 at the same depth position as that of any of the helium chemical concentration peaks 221. The valley portion 35 is a region where the doping concentration shows a local minimum value. In this example, since the lower-surface-side lifetime killer 220 is provided at the same depth position as that of the helium chemical concentration peak 221, the carrier density at this position decreases.

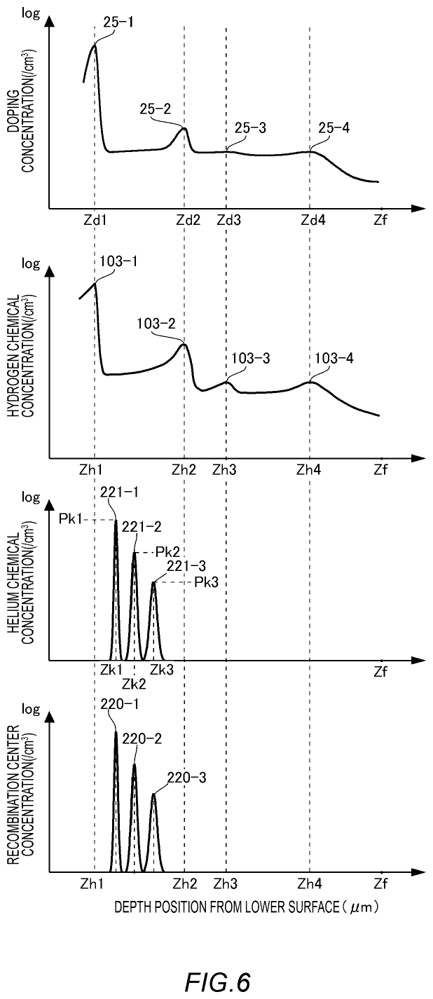

FIG. 6 illustrates a view showing another example of the helium chemical concentration distribution and the recombination center concentration distribution in the buffer region 20. The doping concentration distribution and the hydrogen chemical concentration distribution in FIG. 6 are the same as those in the example of FIG. 5A. The helium chemical concentration distribution in this example has the first helium chemical concentration peak 221-1, the second helium chemical concentration peak 221-2, and the third helium chemical concentration peak 221-3 in order from the lower surface 23 side of the semiconductor substrate 10. The depth positions of the respective helium chemical concentration peaks 221 are set as Zk1, Zk2, and Zk3 in order from the lower surface 23 side. Further, the concentration values of the respective helium chemical concentration peaks 221 are set as Pk1, Pk2, and Pk3 in order from the lower surface 23 side. The recombination center concentration also has a distribution similar to that of the helium chemical concentration.

Also in this example, all helium chemical concentration peaks 221 are arranged between the depth positions Zd1 and Zd2. In another example, any of the helium chemical concentration peaks 221 may be arranged in another region of the buffer region 20.

The first helium chemical concentration peak 221-1 may have a higher concentration value Pk than at least one of the second helium chemical concentration peak 221-2 and the third helium chemical concentration peak 221-3. The first helium chemical concentration peak 221-1 may be the helium chemical concentration peak 221 with the largest concentration value Pk. Further, the concentration value Pk of the helium chemical concentration peak 221 may decrease as a distance from the lower surface 23 of the semiconductor substrate 10 increases. Further, the straggling ΔRp or the full width at half maximum of the helium chemical concentration peak 221 may increase as the distance from the lower surface 23 of the semiconductor substrate 10 increases.

The relative magnitude relationship of the concentrations of the respective lower-surface-side lifetime killers 220 may be the same as the relative magnitude relationship of the concentrations of the corresponding helium chemical concentration peaks 221. That is, the concentration of the lower-surface-side lifetime killer 220 may increase as the concentration of the corresponding helium chemical concentration peak 221 increases.

According to this example, the high-concentration lower-surface-side lifetime killer 220 is arranged in the vicinity of the lower surface 23. Thus, the implantation of hole carriers from the collector region 22 into the drift region 18 can be suppressed. Further, it is possible to suppress an increase in leakage current and to improve tolerance at the time of turn-off or the like.

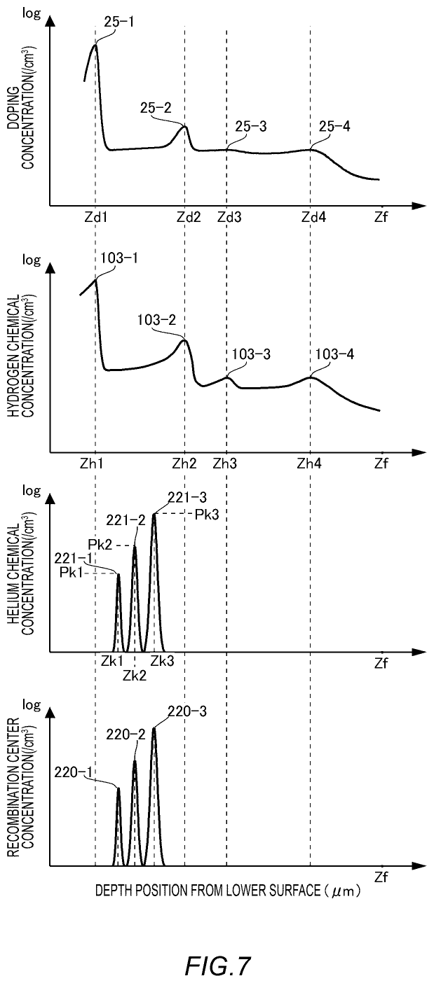

FIG. 7 illustrates a view showing another example of the helium chemical concentration distribution and the recombination center concentration distribution in the buffer region 20. The doping concentration distribution and the hydrogen chemical concentration distribution in FIG. 7 are the same as those in the example of FIG. 5A. The helium chemical concentration distribution of this example is different from that of the example of FIG. 6 in the relative magnitude relationship of the concentrations of the respective helium chemical concentration peaks 221. The other structures are the same as those of the example in FIG. 6. The recombination center concentration also has a distribution similar to that of the helium chemical concentration.

The first helium chemical concentration peak 221-1 may have a lower concentration value Pk than at least one of the second helium chemical concentration peak 221-2 and the third helium chemical concentration peak 221-3. The first helium chemical concentration peak 221-1 may be the helium chemical concentration peak 221 with the smallest concentration value Pk. Further, the concentration value Pk of the helium chemical concentration peak 221 may increase as the distance from the lower surface 23 of the semiconductor substrate 10 increases. Further, the straggling ΔRp or the full width at half maximum of the helium chemical concentration peak 221 may increase as the distance from the lower surface 23 of the semiconductor substrate 10 increases.

According to this example, the high-concentration lower-surface-side lifetime killer 220 is arranged in the vicinity of the drift region 18. Thus, the lifetime of the carrier flowing from the drift region 18 to the lower surface 23 side can be shortened at the time of turning off the semiconductor device 100 or the like. Thus, a period during which the tail current flows can be shortened. Further, it is possible to suppress an increase in leakage current and to improve tolerance at the time of turn-off or the like.

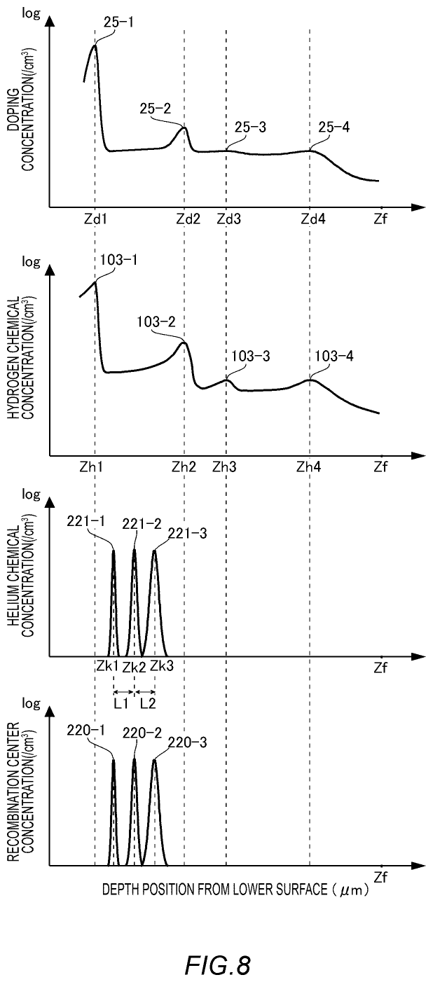

FIG. 8 illustrates a view showing another example of the helium chemical concentration distribution and the recombination center concentration distribution in the buffer region 20. The doping concentration distribution and the hydrogen chemical concentration distribution in FIG. 8 are the same as those in the example of FIG. 5A. In this example, a peak interval between a helium chemical concentration peak 221-k and a helium chemical concentration peak 221-(k+1) in the depth direction is set as Lk (in FIG. 8, L1, L2). The other structures are the same as any of the examples described in FIGS. 5A to 7. The peak interval (in FIG. 8, L1, L2) between two adjacent helium chemical concentration peaks 221 in the depth direction may be uniform in the buffer region 20. The recombination center concentration also has a distribution similar to that of the helium chemical concentration.

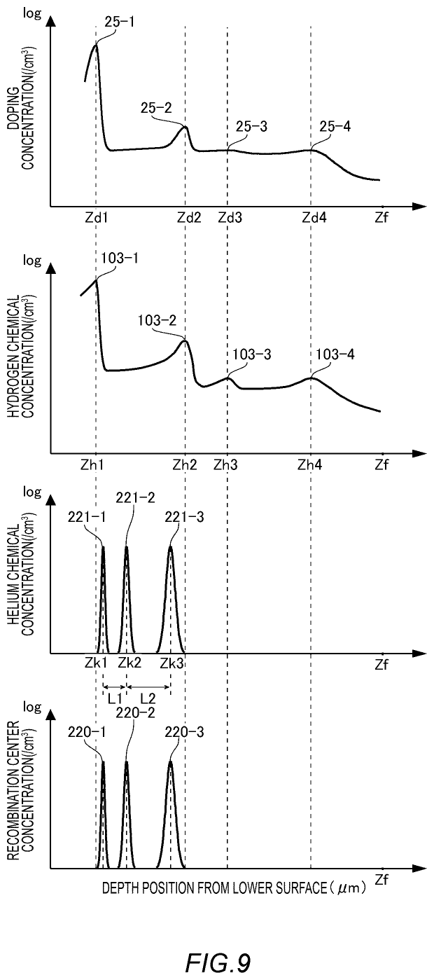

FIG. 9 illustrates a view showing another example of the helium chemical concentration distribution and the recombination center concentration distribution in the buffer region 20. The doping concentration distribution and the hydrogen chemical concentration distribution in FIG. 9 are the same as those in the example of FIG. 5A. In this example, each peak interval Lk is different from that of the example of FIG. 8. The other structures are the same as those of the example in FIG. 8.

In this example, the first peak interval L1 is smaller than the second peak interval L2 at a position farther away from the lower surface 23 than the first peak interval L1 (L1<L2). That is, in the buffer region 20, the helium chemical concentration peak 221 is arranged at a higher density toward the lower surface 23. The recombination center concentration also has a distribution similar to that of the helium chemical concentration.

According to this example, many lower-surface-side lifetime killers 220 can be formed in the vicinity of the collector region 22. Thus, the implantation of hole carriers from the collector region 22 into the drift region 18 can be suppressed.

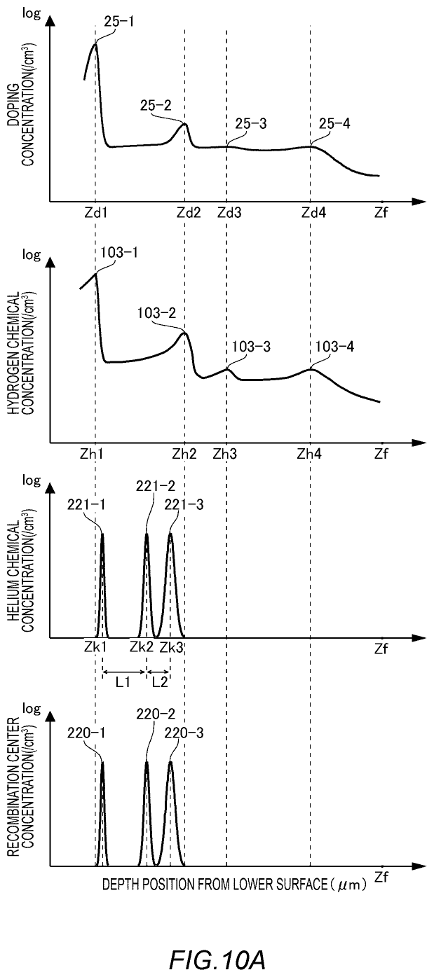

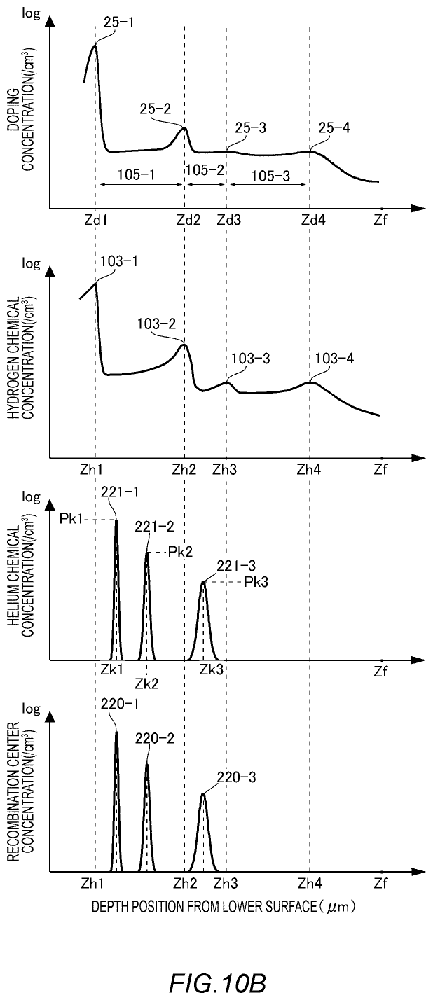

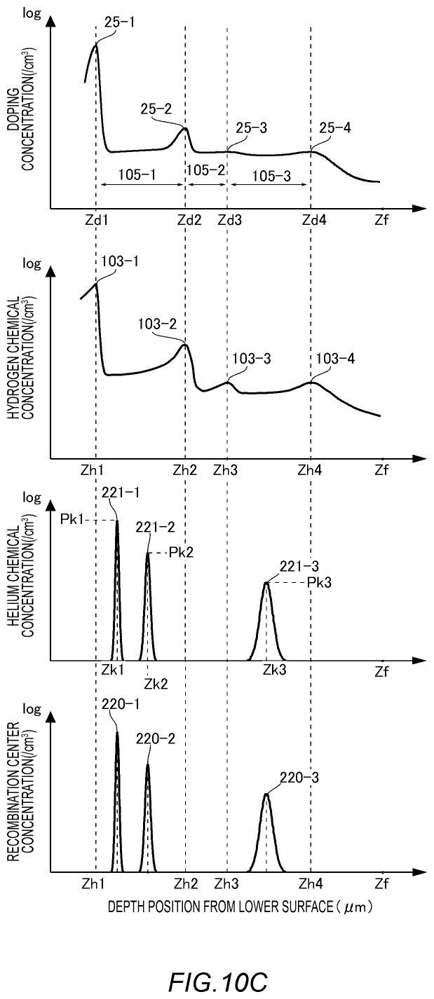

FIG. 10A illustrates a view showing another example of the helium chemical concentration distribution and the recombination center concentration distribution in the buffer region 20. The doping concentration distribution and the hydrogen chemical concentration distribution in FIG. 10A are the same as those in the example of FIG. 5A. In this example, each peak interval Lk is different from that of the example of FIG. 8. The other structures are the same as those of the example in FIG. 8.

In this example, the first peak interval L1 is larger than the second peak interval L2 (L1>L2). That is, in the buffer region 20, the helium chemical concentration peak 221 is arranged at a higher density toward the drift region 18. The recombination center concentration also has a distribution similar to that of the helium chemical concentration.

According to this example, many lower-surface-side lifetime killers 220 can be formed in the vicinity of the drift region 18. Thus, the lifetime of the carrier flowing from the drift region 18 to the lower surface 23 side can be shortened at the time of turning off the semiconductor device 100 or the like. Thus, a period during which the tail current flows can be shortened.

FIG. 10B illustrates a view showing another example of the helium chemical concentration distribution and the recombination center concentration distribution in the buffer region 20. The doping concentration distribution and the hydrogen chemical concentration distribution in FIG. 10B are the same as those in the example of FIG. 5A.

A region between two adjacent doping concentration peaks 25 in the depth direction is set as an inter-peak region 105. A region between two adjacent hydrogen chemical concentration peaks 103 in the depth direction may be set as the inter-peak region 105. In this example, a region between the depth positions Zd1 and Zd2 (or Zh1 and Zh2) is set as an inter-peak region 105-1, a region between the depth positions Zd2 and Zd3 (or Zh2 and Zh3) is set as an inter-peak region 105-2, and a region between the depth positions Zd3 and Zd4 (or Zh3 and Zh4) is set as an inter-peak region 105-3.

In this example, the helium chemical concentration peaks 221 are arranged in two or more inter-peak regions 105. The helium chemical concentration peak 221 may be arranged in two inter-peak regions 105 adjacent to each other. One or more helium chemical concentration peaks 221 may be arranged in each inter-peak region 105. More helium chemical concentration peaks 221 may be arranged closer to the lower surface 23 in the inter-peak region 105. In the example of FIG. 10B, two helium chemical concentration peaks 221 are arranged in the inter-peak region 105-1, and one helium chemical concentration peak 221 is arranged in the inter-peak region 105-2.

The magnitude relationship of the concentrations of the respective helium chemical concentration peaks 221 may be similar to that of any of the examples described in FIGS. 5A to 10A. In the example of FIG. 10B, the concentration of the helium chemical concentration peak 221 decreases as the distance from the lower surface 23 increases. The interval of the helium chemical concentration peaks 221 may be similar to that of any of the examples described in FIGS. 5A to 10A. The recombination center concentration may also have a distribution similar to that of the helium chemical concentration.

FIG. 10C illustrates a view showing another example of the helium chemical concentration distribution and the recombination center concentration distribution in the buffer region 20. The doping concentration distribution and the hydrogen chemical concentration distribution in FIG. 10C are the same as those in the example of FIG. 5A.

In this example, the helium chemical concentration peak 221 is not arranged in the inter-peak region 105 between two inter-peak regions 105 where the helium chemical concentration peaks 221 are arranged. In the example of FIG. 10C, two helium chemical concentration peaks 221 are arranged in the inter-peak region 105-1, no helium chemical concentration peak 221 is arranged in the inter-peak region 105-2, and one helium chemical concentration peak 221 is arranged in the inter-peak region 105-3. The concentration of each helium chemical concentration peak 221 may be similar to that of the example of FIG. 10B. The recombination center concentration may also have a distribution similar to that of the helium chemical concentration.

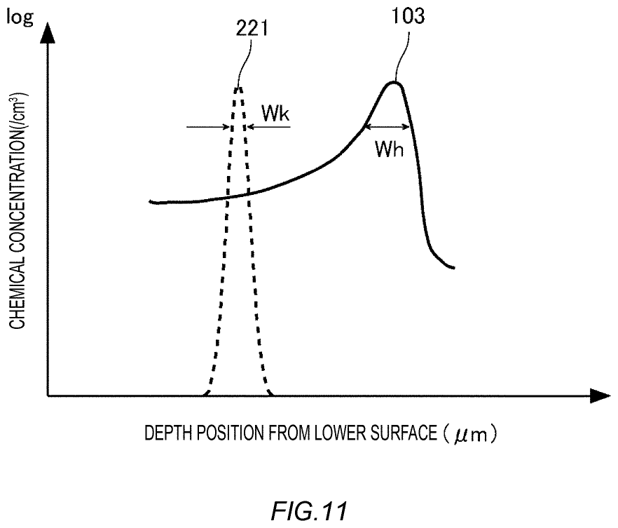

FIG. 11 illustrates the full width at half maximum Wk of the helium chemical concentration peak 221. In this example, the full width at half maximum of the hydrogen chemical concentration peak 103 is set as Wh. In FIG. 11, only one helium chemical concentration peak 221 and one hydrogen chemical concentration peak 103 are shown, and the other peaks are omitted.

The full width at half maximum Wk of each helium chemical concentration peak 221 is smaller than the full width at half maximum Wh of any hydrogen chemical concentration peak 103 arranged farther away from the lower surface 23 of the semiconductor substrate than each helium chemical concentration peak 221. For example, the full width at half maximum of each of the helium chemical concentration peaks 221-1, 221-2, and 221-3 shown in FIG. 10A is smaller than the full width at half maximum of any of the hydrogen chemical concentration peaks 103-2, 103-3, and 103-4. Each full width at half maximum Wk may be equal to or less than half of the full width at half maximum Wh of the hydrogen chemical concentration peak 103 farther away from lower surface 23. By reducing the full width at half maximum Wk of the helium chemical concentration peak 221, it is possible to suppress a change in the shape of the doping concentration distribution of the buffer region 20 over a wide range.

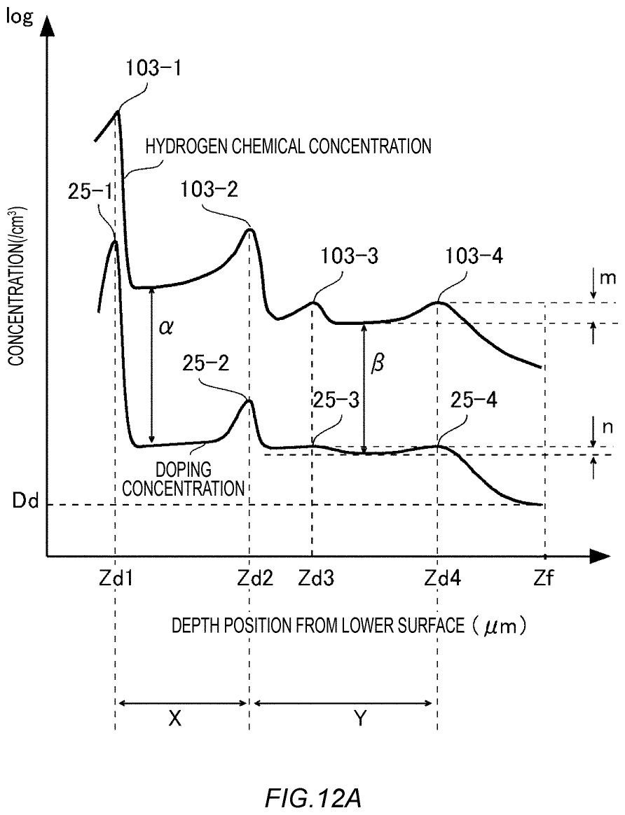

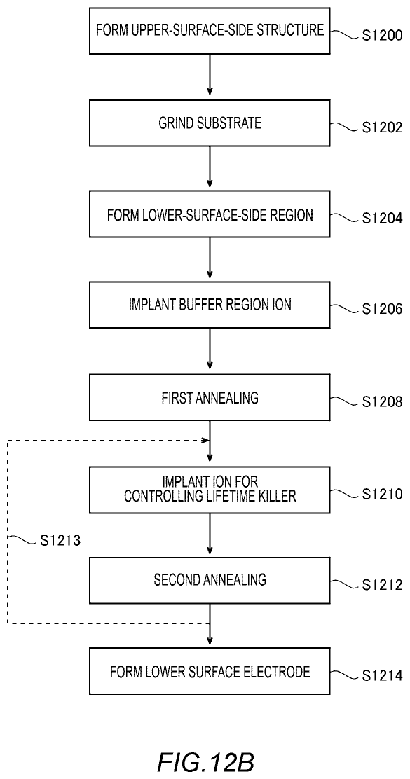

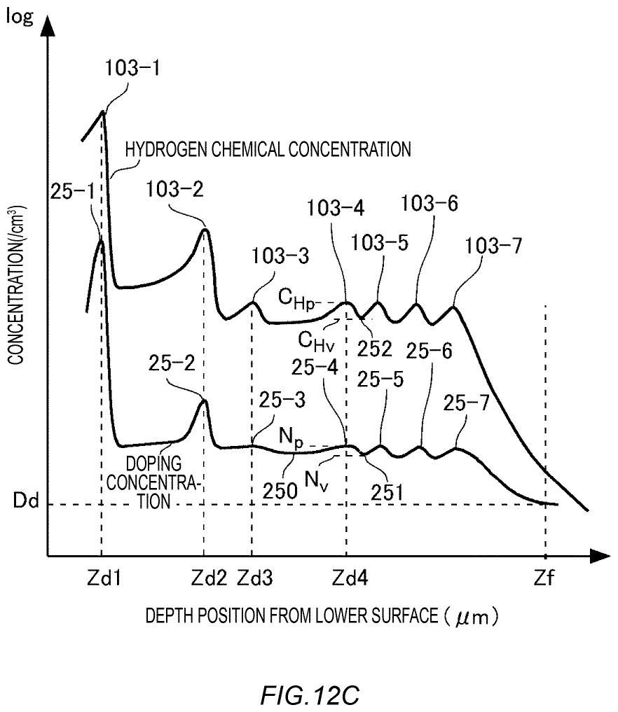

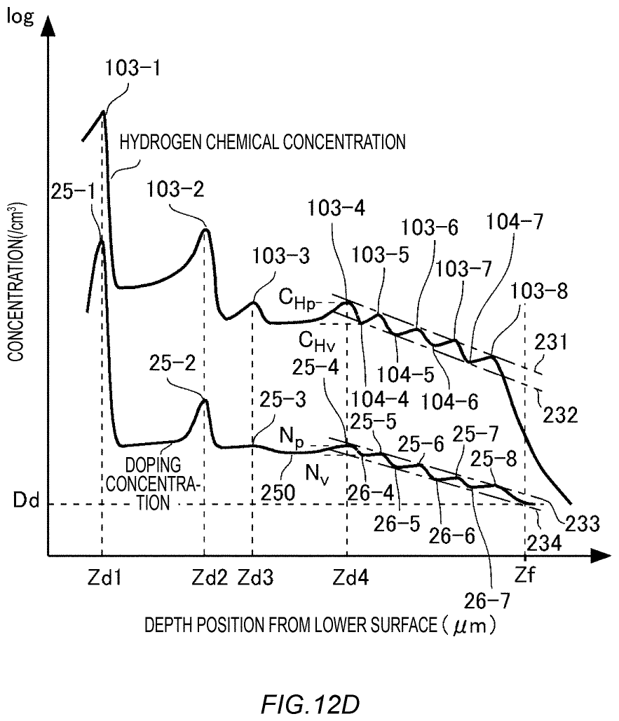

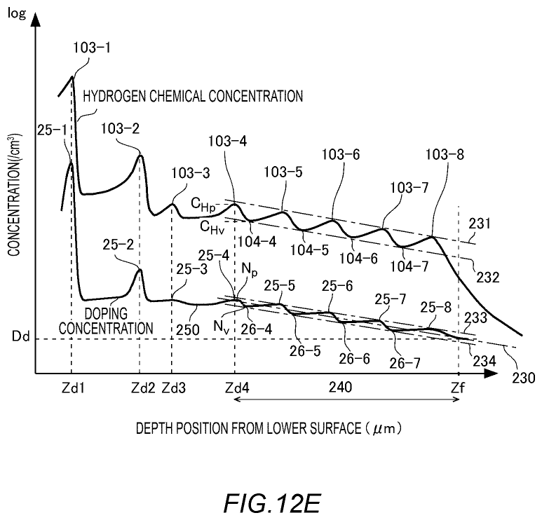

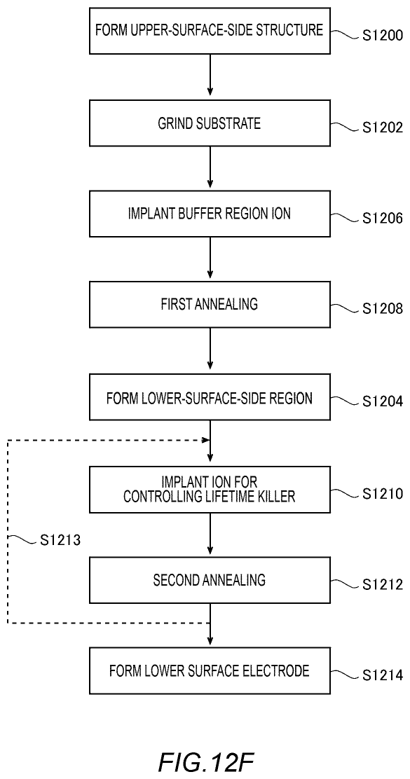

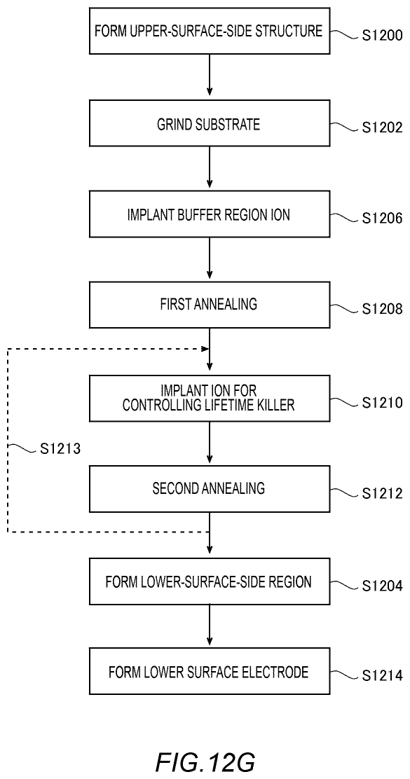

FIG. 12A illustrates a view showing an example of the doping concentration distribution and the hydrogen chemical concentration distribution in the buffer region 20. The doping concentration distribution and the hydrogen chemical concentration distribution may be similar to those in the examples described in FIGS. 5A to 11. Further, the helium chemical concentration distribution is the same as that of any of the examples described in FIGS. 5A to 11.

In this example, the two doping concentration peaks 25-3 and 25-4 farthest away from the lower surface 23 of the semiconductor substrate 10 are not observed as clear concentration peaks. A ratio of the minimum value of the doping concentration in the region between the doping concentration peak 25-3 and the doping concentration peak 25-4 to the larger one of the concentration values of the doping concentration peak 25-3 and the doping concentration peak 25-4 is set as n. The ratio n may be 50% or less, may be 20% or less, or may be 10% or less.

Further, a ratio of the minimum value of the hydrogen chemical concentration in the region between the hydrogen chemical concentration peak 103-3 and the hydrogen chemical concentration peak 103-4 to the larger one of the concentration values of two hydrogen chemical concentration peaks 103-3 and 103-4 farthest away from lower surface 23 of semiconductor substrate 10 is set as m. The ratio m may be larger than the ratio n. That is, in a range from the depth position Zd3 to Zd4, the amplitude of a fluctuation in the hydrogen chemical concentration distribution may be larger than the amplitude of a fluctuation in the doping concentration distribution.

Further, a region from the depth position Zd1 to the depth position Zd2 is set as a region X, and a region from the depth position Zd2 to the depth position Zd4 is set as a region Y. In the region X, a ratio of the minimum value of the hydrogen chemical concentration to the minimum value of the doping concentration is set as α. Similarly, in the region Y, a ratio of the minimum value of the hydrogen chemical concentration to the minimum value of the doping concentration is set as β. The ratio α may be larger than the ratio β. Further, in the depth direction, the region Y may be longer than the region X. The length of the region Y may be 1.5 times or more the length of the region X, or may be 2 times or more the length of the region X.

FIG. 12B illustrates a view showing some processes in a manufacturing method of the semiconductor device 100. In this example, in an upper-surface-side structure forming step S1200, the structure on the upper surface 21 side of the semiconductor substrate 10 is formed. The structure on the upper surface 21 side may include at least one of doped regions, such as the emitter region 12, the base region 14, and the accumulation region 16, on the upper surface 21 side of the semiconductor substrate 10. The structure on the upper surface 21 side may include each trench portion. The structure on the upper surface 21 side may include a structure such as the emitter electrode 52 above the upper surface 21 of the semiconductor substrate 10. The structure on the upper surface 21 side may include the edge termination structure portion 90.

Next, in a substrate grinding step S1202, the lower surface 23 of the semiconductor substrate 10 is ground to thin the semiconductor substrate 10. In S1202, the semiconductor substrate 10 may be thinned to a thickness corresponding to the breakdown voltage to be possessed by the semiconductor device 100.

Next, in a lower-surface-side region forming step S1204, the lower surface doped region of the semiconductor substrate 10 is formed. The lower surface doped region is a doped region in contact with an electrode, such as the collector electrode 24 formed in a later process, formed on the lower surface 23. The lower surface doped region may include at least one of the cathode region 82 and the collector region 22.

Next, in a first ion implantation step S1206, ions for forming the buffer region 20 are implanted into the semiconductor substrate 10. In S1206, ions may be implanted from the lower surface 23 of the semiconductor substrate 10 into a region where the buffer region 20 is to be formed. In S1206, a donor ion such as a hydrogen ion (for example, a proton) or a phosphorous ion may be implanted.

Next, in a first annealing step S1208, the semiconductor substrate 10 is thermally annealed. In S1208, the semiconductor substrate 10 may be put into an electric furnace to anneal the entire semiconductor substrate 10 (or a wafer). The annealing temperature in S1208 may be 320 degrees C. or higher and 420 degrees C. or lower. In S1208, annealing may be performed in an atmosphere containing hydrogen and nitrogen.

Next, in a second ion implantation step S1210, ions for forming the lower-surface-side lifetime killer 220 are implanted into the semiconductor substrate 10. In S1210, ions may be implanted from the lower surface 23 of the semiconductor substrate 10. In S1210, hydrogen ions such as protons or helium ions may be implanted. In this example, helium ions are implanted.

In S1210, the lower-surface-side lifetime killer 220 described in FIGS. 5A to 10C is formed. The lower-surface-side lifetime killers 220 can be formed at a plurality of positions in the depth direction by sequentially changing the acceleration energy of helium ions or the like. In S1210, helium ions or the like may be implanted in order from a position close to the lower surface 23 among the plurality of positions in the depth direction, or helium ions or the like may be implanted in order from a position far from the lower surface 23. In this example, helium ions are implanted in order from a position far from the lower surface 23. Further, in S1210, ions may be implanted in order from the lower-surface-side lifetime killer 220 having a large dose amount, or ions may be implanted in order from the lower-surface-side lifetime killer 220 having a small dose amount.

Next, in the second annealing step S1212, the semiconductor substrate 10 is thermally annealed. In S1212, the semiconductor substrate 10 may be put into an electric furnace to anneal the entire semiconductor substrate 10 (or a wafer). The annealing temperature in S1212 may be lower than the annealing temperature in S1208. The annealing temperature in S1212 may be 300 degrees C. or higher and 400 degrees C. or lower. In S1212, annealing may be performed in a nitrogen atmosphere or an atmosphere containing hydrogen and nitrogen.

S1212 may be performed each time helium ions or the like are implanted into one depth position in S1210, or may be performed each time helium ions or the like are implanted into a plurality of depth positions. A set of processes of S1210 and S1212 may be repeated a plurality of times (S1213).

Next, in a lower surface electrode forming step S1214, an electrode in contact with the lower surface 23 is formed. In S1214, the collector electrode 24 may be formed. Through such a process, the semiconductor device 100 can be formed.

FIG. 12C illustrates a view showing another example of the doping concentration distribution and the hydrogen chemical concentration distribution in the buffer region 20. Except for the matters particularly described or illustrated in FIG. 12C, the doping concentration distribution and the hydrogen chemical concentration distribution are similar to those in the example of FIG. 12A. The doping concentration distribution in the buffer region 20 of this example has a flat portion 250 between any two doping concentration peaks 25. The flat portion 250 is a region where the variation of the doping concentration in a predetermined depth range is within a predetermined variation range. The depth range may be 0.5 μm or more, or may be 1 μm or more. The variation range may be ±30% or less of the average value of the concentrations at both ends of the depth range, may be ±20% or less, or may be ±10% or less. The variation range of the concentration distribution is a difference between the maximum value and the minimum value of the doping concentration in the region.

Further, in the flat portion 250, a variation ratio R1 of the doping concentration is less than a variation ratio R2 of the hydrogen chemical concentration. The variation ratio of the concentration distribution is a ratio of the maximum value to the minimum value of the concentration in the region. That is, the variation ratio is a value obtained by dividing the maximum value of the concentration by the minimum value. The variation ratio R1 may be half or less of the variation ratio R2, may be ¼ or less, or may be 1/10 or less.

Further, the peak width of the doping concentration peak 25 in the flat portion 250 may be larger than the peak width of the corresponding hydrogen chemical concentration peak 103. The peak width of the doping concentration peak 25 in the flat portion 250 may be a distance between the minimum portion on the upper surface 21 side and the minimum portion on the lower surface 23 side in the doping concentration peak 25. In the flat portion 250, the maximum value of the doping concentration may be 50% or less of the minimum value. In this case, the minimum value of the doping concentration is 50% or more of the maximum value, and a full width at half maximum FWHM of the doping concentration peak 25 cannot be defined. When the full width at half maximum FWHM of the doping concentration peak 25 can be measured, the full width at half maximum FWHM may be used as the peak width of the doping concentration peak 25. The full width at half maximum FWHM may be used as the peak width of the hydrogen chemical concentration peak 103.

In the example of FIG. 12C, the flat portion 250 is arranged between the doping concentration peak 25-3 and the doping concentration peak 25-4. The doping concentration in the flat portion 250 is larger than the doping concentration Dd of the drift region 18. The doping concentration in the flat portion 250 may be 2.5 times or more the doping concentration Dd of the drift region 18.

The buffer region 20 may have a plurality of doping concentration peaks 25 having no flat portion between peaks on the upper surface 21 side of the flat portion 250. The definition of the flat portion is similar to that of the flat portion 250. The buffer region 20 in the example of FIG. 12C has the doping concentration peaks 25-4, 25-5, 25-6, and 25-7 on the upper surface 21 side of the flat portion 250. The value of the doping concentration peak 25 on the upper surface 21 side of the flat portion 250 may be substantially the same, or may decrease as the distance from the lower surface 23 increases. The term “substantially the same” may refer to 30% or less of the variation of the adjacent doping concentration peaks 25, may refer to 20% or less, or may refer to 10% or less.

In the plurality of doping concentration peaks 25 having no flat portion between the peaks, the valley portions 251 may be provided between the peaks. In each valley portion 251, the gradient (differential value) of the doping concentration distribution may continuously change from a negative value to a positive value in a direction from the lower surface 23 toward the upper surface 21. On the other hand, in the flat portion 250, the gradient of the doping concentration distribution may have a continuous value of substantially zero in the direction from the lower surface 23 toward the upper surface 21. Note that the gradient of the doping concentration distribution may be the average value of a plurality of measurement points in a predetermined measurement range, the measurement points being based on the CV profiling or the SRP method, or the average value may be a value calculated by well-known fitting.

Further, the positions in the depth direction of the plurality of doping concentration peaks 25 having no flat portion between peaks correspond to the positions in the depth direction of the hydrogen chemical concentration peaks 103. Each doping concentration peak 25 arranged closer to the upper surface 21 side than the flat portion 250 and the corresponding hydrogen chemical concentration peak 103 may have the following relationship.

C_{Hv}/C_{Hp}<Nᵥ/Nₚ

Note that C_{Hp} is the concentration of the hydrogen chemical concentration peak 103, C_{Hv} is the concentration of the valley portion 252 adjacent to the hydrogen chemical concentration peak 103 on the upper surface 21 side, Nₚ is the concentration of the doping concentration peak 25, and Nᵥ is the concentration of the valley portion 251 adjacent to the doping concentration peak 25 on the upper surface 21 side. C_{Hv}/C_{Hp} may be 0.8 times or less of Nᵥ/Nₚ, may be 0.5 times or less, may be 0.2 times or less, may be 0.1 times or less, or may be 0.01 times or less. C_{Hv}/C_{Hp} may be 0.001 times or more of Nᵥ/Nₚ, may be 0.01 times or more, or may be 0.1 times or more.

Since the semiconductor device 100 has the plurality of doping concentration peaks 25 having no flat portion between peaks on the upper surface 21 side of the flat portion 250, the distribution of the doping concentration can be made gentle, and a change in an electric field intensity when the depletion layer reaches the buffer region 20 can be made gentle. With this configuration, a sudden change in a voltage waveform can be suppressed.

FIG. 12D illustrates a view showing still another example of the doping concentration distribution and the hydrogen chemical concentration distribution in the buffer region 20. Except for the matters particularly described or illustrated in FIG. 12D, the doping concentration distribution and the hydrogen chemical concentration distribution are similar to those in the example of FIG. 12C. In the buffer region 20 of this example, the concentration of the doping concentration peak 25 on the upper surface 21 side of the flat portion 250 decreases toward the upper surface 21. Further, the concentration of the hydrogen chemical concentration peak 103 on the upper surface 21 side of the flat portion 250 also decreases toward the upper surface 21. With such a structure, the variation of the doping concentration of the buffer region 20 in the vicinity of the drift region 18 can be made gentle.

The concentration of the hydrogen chemical concentration peak 103-k on the upper surface 21 side of the flat portion 250 may be half or less of the concentration of the hydrogen chemical concentration peak 103-(k−1) adjacent on the lower surface 23 side, or may be ¼ or less. The concentration of the hydrogen chemical concentration peak 103-k may be 1/10 or more of the concentration of the hydrogen chemical concentration peak 103-(k−1). The concentration of the doping concentration peak 25-k on the upper surface 21 side of the flat portion 250 may be half or less of the concentration of the doping concentration peak 25-(k−1) adjacent on the lower surface 23 side, or may be ¼ or less. The concentration of the doping concentration peak 25-k may be 1/10 or more of the concentration of the doping concentration peak 25-(k−1). Also in this example, the fluctuation (a difference between Nᵥ and Nₚ) in the doping concentration on the upper surface 21 side of the flat portion 250 is smaller than the fluctuation (a difference between C_{HV} and C_{Hp}) in the hydrogen chemical concentration. Further, the half-value width of the doping concentration peak 25 is larger than the half-value width of the hydrogen chemical concentration peak 103.

An envelope connecting the hydrogen chemical concentration peaks 103-k is set as a hydrogen peak envelope 231. An envelope connecting the valley portions 104-k of the hydrogen chemical concentration is set as a hydrogen valley portion envelope 232. Further, an envelope connecting the doping concentration peak 25-k is set as a doping peak envelope 233. An envelope connecting the valley portions 26-k of the doping concentration is set as a doping valley portion envelope 234. At any position X between the position Zd4 and the position Zf, a first ratio of the hydrogen peak envelope 231 to the hydrogen valley portion envelope 232 may be larger than a second ratio of the doping peak envelope 233 to the doping valley portion envelope 234. The first ratio may be larger than 2 times the second ratio, or may be larger than 3 times. Since the semiconductor device 100 has the plurality of doping concentration peaks 25 on the upper surface 21 side of the flat portion 250 and has the configuration in which the plurality of doping concentration peaks 25 decreases, the distribution of the doping concentration can be made gentle, and the change in the electric field intensity when the depletion layer reaches the buffer region 20 can be made gentle. With this configuration, a sudden change in a voltage waveform can be suppressed.

FIG. 12E illustrates a view showing another example of the doping concentration distribution and the hydrogen chemical concentration distribution in the buffer region 20. Except for the matters particularly described or illustrated in FIG. 12E, the doping concentration distribution and the hydrogen chemical concentration distribution are similar to those in the example of FIG. 12D. In the buffer region 20 of this example, the doping concentration distribution gently varies in an adjacent region 240 in contact with the drift region 18. The adjacent region 240 includes a plurality of hydrogen chemical concentration peaks 103 and is a region where the concentration of the hydrogen chemical concentration peak 103 decreases as the distance from the lower surface 23 increases. The adjacent region 240 of this example is a region from the depth position Zd4 to Zf. A region between the drift region 18 and the flat portion 250 arranged closest to the upper surface 21 side in the buffer region 20 may be set as the adjacent region 240.

In this example, a range (that is, a width) of the adjacent region 240 in the depth direction is larger than that in the example of FIG. 12D. The range of the adjacent region 240 can be adjusted by the interval between the hydrogen chemical concentration peaks 103 arranged on the upper surface 21 side of the flat portion 250. The adjacent region 240 may occupy 30% or more of the buffer region 20 (Zd1 to Zf) in the depth direction, or may occupy 50% or more. The width (Zf−Zd4) of the adjacent region 240 in the depth direction may be larger than the width (Zd4−Zd3) of the flat portion 250 in the depth direction. The width (Zf−Zd4) may be 2 times or more the width (Zd4−Zd3), may be 3 times or more, or may be 5 times or more.

The doping concentration distribution in the adjacent region 240 is approximated by a straight line 230. The straight line 230 can be calculated by a least-squares method or the like. A slope α of the straight line 230 in the adjacent region 240 may be expressed using a semi-logarithmic slope. The position of one end of the adjacent region 240 is x1 [cm], and the position of the other end is x2 [cm]. In the example of FIG. 12E, x1 corresponds to the depth position Zd4, and x2 corresponds to the depth position Zf. The doping concentration in x1 is set as N1 [/cm³], and the doping concentration in x2 is set as N2 [/cm³]. The slope a of the straight line 230 is given by the following equation.

α=(|log₁₀(N2)−log₁₀(N1)|)/(|x2−x1|)

The slope α of the straight line 230 of this example may be 20 (/cm) or more and 200 (/cm) or less. The slope α may be 40 (/cm) or more, or may be 60 (/cm) or more. The slope α may be 180 (/cm) or less, or may be 160 (/cm) or less. By making the slope α of the straight line 230 gentle, the expanding of the depletion layer (space charge region) reaching the adjacent region 240 at the time of switching of the semiconductor device 100 can be made gentle.

FIG. 12F illustrates a view showing another example of the processes in the manufacturing method of the semiconductor device 100. The manufacturing method of this example is different from the example of FIG. 12B in that the lower-surface-side region forming step S1204 is performed after the first annealing step S1208 and before the second ion implantation step S1210. Other processes are similar to those of the example of FIG. 12B.

The first ion implantation step S1206 may include processes S1601 to S1604 described below. In this case, the doping concentration peak 25 closest to the lower surface 23 in the buffer region 20 can be formed without loss. Thus, even when the collector region 22 is formed in the lower-surface-side region forming step S1204 after the first ion implantation step S1206, there is no problem that the depletion layer reaches the collector region 22 as described below.

FIG. 12G illustrates a view showing another example of the processes in the manufacturing method of the semiconductor device 100. The manufacturing method of this example is different from the example of FIG. 12B in that the lower-surface-side region forming step S1204 is performed after the second annealing step S1212 and before the lower surface electrode forming step S1214. Other processes are similar to those of the example of FIG. 12B.

Also in this example, the first ion implantation step S1206 may include processes S1601 to S1604 described below. In this case, the doping concentration peak 25 closest to the lower surface 23 in the buffer region 20 can be formed without loss. Thus, even when the collector region 22 is formed in the lower-surface-side region forming step S1204 after the first ion implantation step S1206, there is no problem that the depletion layer reaches the collector region 22 as described below.

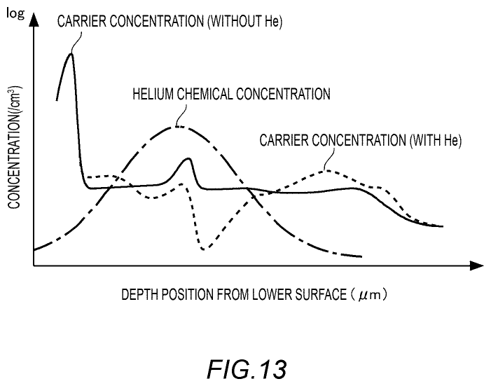

FIG. 13 shows an example of the carrier concentration distribution and the helium chemical concentration distribution in the buffer region 20 of a comparative example. The buffer region 20 of this example has only one peak of helium chemical concentration formed by implanting ³He. Further, in FIG. 13, the carrier concentration distribution when helium is not implanted is indicated by a solid line, and the carrier concentration distribution when helium is implanted is indicated by a broken line. The carrier concentration distribution when helium is not implanted is similar to the doping concentration distribution in FIG. 5A or the like.

In this example, a single helium chemical concentration peak is provided in the buffer region 20. Thus, it is difficult to control the distribution of the lifetime killer. Further, when the half-value width of the helium chemical concentration peak is large, the carrier concentration distribution varies in a wide range as compared with a case where helium is not implanted. In contrast, in the example of FIGS. 1 to 12B, since the plurality of helium chemical concentration peaks are arranged in the buffer region 20, the distribution of the lifetime killer can be adjusted precisely. Further, by reducing the half-value width of the helium chemical concentration peak, it is possible to suppress the variation of the carrier concentration distribution in a wide range.

### Second Example

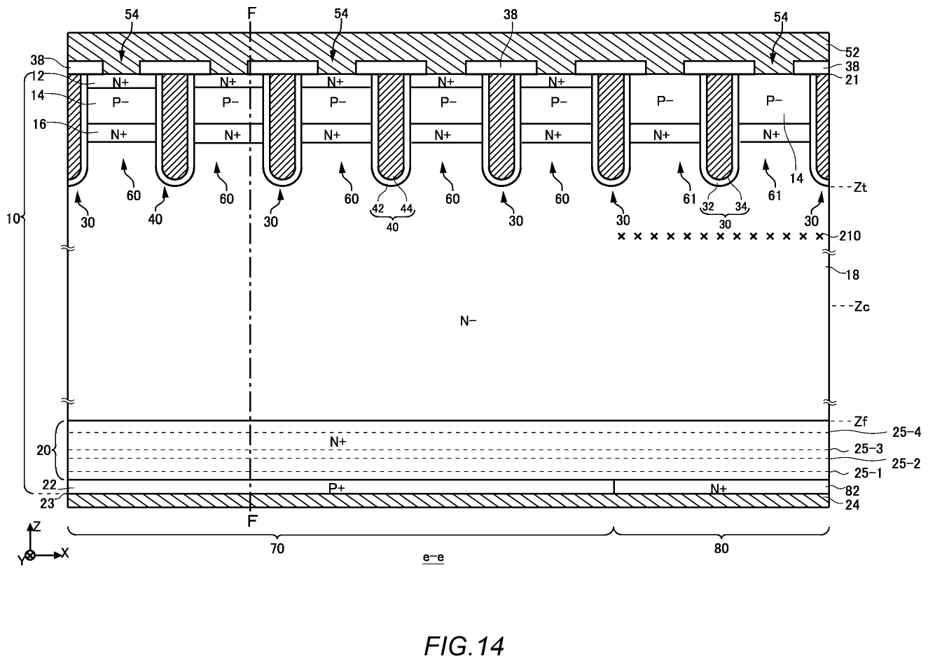

FIG. 14 illustrates a view showing another example of the cross section e-e. In the semiconductor device 100 of the this example, the method of forming the buffer region 20 is different from that of the first example described in FIGS. 1 to 13. The method of forming the buffer region 20 will be described below. The other portions are similar to those in the first example Note that in the semiconductor device 100 of this example, the lower-surface-side lifetime killer 220 may be provided in the buffer region 20, or may not be provided. That is, the helium chemical concentration peak 221 may be provided in the buffer region 20, or may not be provided.

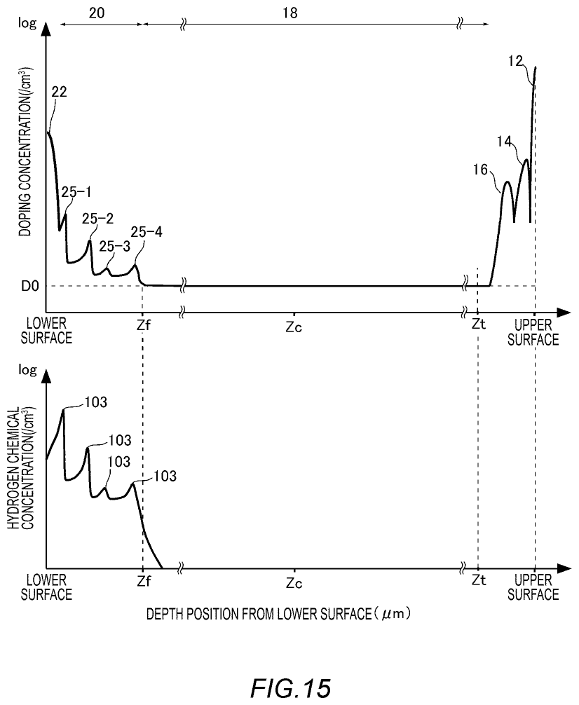

FIG. 15 illustrates a view showing an example of the doping concentration distribution and the hydrogen chemical concentration distribution taken along line F-F in FIG. 14. The doping concentration distribution and the hydrogen chemical concentration distribution may be similar to those of the example of FIG. 5A. Note that although FIG. 15 shows an example in which each doping concentration peak in the doping concentration distribution can be clearly observed, any doping concentration peak may not be clearly observed as in the example of FIG. 5A.

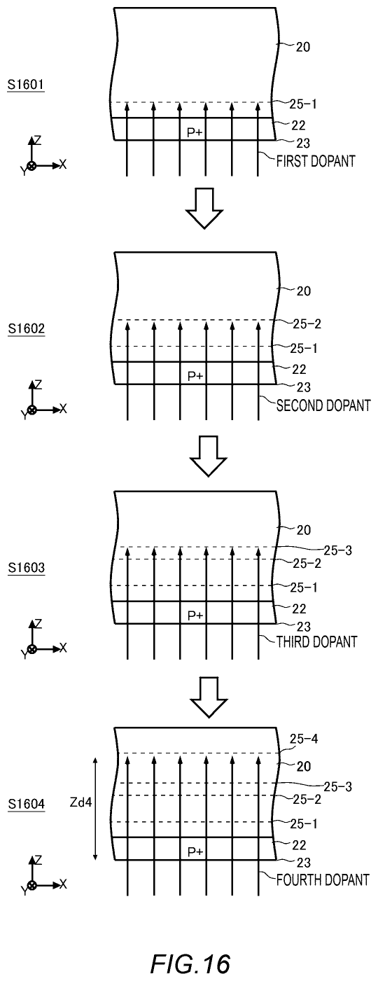

FIG. 16 illustrates a view showing an example of the method of forming the buffer region 20. FIG. 16 shows an implantation process of implanting a dopant into the buffer region 20. First, a first dopant of the N type is implanted into a first implantation position from the implantation surface of the semiconductor substrate 10 (S1601). In this example, the implantation surface is the lower surface 23, and the first implantation position is the depth position Zd1 (or Zh1) described in FIG. 5A and the like. Further, the first dopant is, for example, a hydrogen ion or a phosphorous ion.

After the first dopant is implanted, a second dopant of the N type is implanted from the implantation surface (the lower surface 23 in this example) of the semiconductor substrate 10 into a second implantation position having a larger distance from the implantation surface than the first implantation position (S1602). In this example, the second implantation position is the depth position Zd2 (or Zh2) described in FIG. 5A and the like. Further, the second dopant is, for example, a hydrogen ion or a phosphorous ion. The second dopant may be the same element as the first dopant. For example, both the first dopant and the second dopant are hydrogen ions. In another example, one of the first dopant and the second dopant may be a phosphorous ion, and the other may be a hydrogen ion.

After the second dopant is implanted, a third dopant of the N type is implanted from the implantation surface (the lower surface 23 in this example) of the semiconductor substrate 10 into a third implantation position having a larger distance from the implantation surface than the second implantation position (S1603). In this example, the third implantation position is the depth position Zd3 (or Zh3) described in FIG. 5A and the like. Further, the third dopant is, for example, a hydrogen ion or a phosphorous ion. The third dopant may be the same element as the first dopant or the second dopant. For example, the first dopant, the second dopant, and the third dopant are all hydrogen ions. In another example, a part of the first dopant, the second dopant, and the third dopant may be hydrogen ions, and a part thereof may be phosphorous ions.

After the third dopant is implanted, a fourth dopant of the N type is implanted from the implantation surface (the lower surface 23 in this example) of the semiconductor substrate 10 into a fourth implantation position having a larger distance from the implantation surface than the third implantation position (S1604). In this example, the fourth implantation position is the depth position Zd4 (or Zh4) described in FIG. 5A and the like. Further, the fourth dopant is, for example, a hydrogen ion or a phosphorous ion. The fourth dopant may be the same element as the first dopant, the second dopant, or the third dopant. For example, the first dopant, the second dopant, the third dopant, and the fourth dopant are all hydrogen ions. In another example, a part of the first dopant, the second dopant, the third dopant, and the fourth dopant may be hydrogen ions, and a part thereof may be phosphorous ions.

In the implantation process, three or more N-type dopants including the first dopant and the second dopant may be implanted from the implantation surface of the semiconductor substrate 10 into the implantation positions having different depths from each other. In the example of FIG. 16, the dopant is implanted into four depth positions, but it is sufficient if the dopant is implanted into two or more depth positions.

When the dopant is implanted into the semiconductor substrate 10, foreign matter such as particles may adhere to the implantation surface. When the dopant is further implanted from the implantation surface in a state where the foreign matter adheres to the implantation surface, the dopant is shielded by the foreign matter, and the dopant may not be able to be implanted precisely. In particular, when a distance between the depth position into which the dopant is implanted and the implantation surface is short, the acceleration energy of the dopant is small, and thus the dopant is easily shielded by the foreign matter.

According to this example, after the first dopant is implanted, the second dopant is implanted at a deeper position. Thus, even when the foreign matter adheres to the implantation surface in the process of implanting the second dopant (S1602), the implantation of the first dopant is not affected. Thus, the implantation of the first dopant having a relatively small acceleration energy can be performed precisely.

In the implantation process, it is preferable to initially implant a dopant to be implanted into the implantation position closest to the lower surface 23 of the semiconductor substrate 10 among the plurality of dopants to be implanted into the buffer region 20. In this example, the first dopant to be implanted into the implantation position closest to the lower surface 23 is implanted initially. Accordingly, the implantation of the first dopant having the smallest acceleration energy can be performed precisely. In another example, the buffer region 20 may include a dopant that is implanted after the first dopant and that is implanted closer to the lower surface 23 than the first dopant.

In the implantation process, among the plurality of dopants to be implanted into the buffer region 20, a dopant to be implanted into the implantation position farthest from the lower surface 23 of the semiconductor substrate 10 may be implanted finally. In this example, the fourth dopant to be implanted into the implantation position farthest from the lower surface 23 is implanted finally. Accordingly, the implantation of each dopant having acceleration energy smaller than that of the fourth dopant can be performed precisely.

Further, as illustrated in FIG. 16, in the implantation process, dopants may be implanted in order from an implantation position close to the lower surface 23 of the semiconductor substrate 10. Accordingly, the dopants can be implanted in order from the dopant having smaller acceleration energy, and thus the implantation of each dopant can be performed precisely.

A distance between the depth position Zd4, which is farthest from the lower surface 23 of the semiconductor substrate 10 among the implantation positions of the plurality of dopants to be implanted into the buffer region 20, and the lower surface 23 of the semiconductor substrate 10 may be half or less of the thickness of the semiconductor substrate 10. That is, the depth position Zd4 is arranged between the center position Zc (see FIG. 4A) of the semiconductor substrate 10 and the lower surface 23. In the manufacturing process of the semiconductor device 100, dopants of the same conductivity type to be implanted from the same implantation surface (the lower surface 23 in this example) into a region on the implantation surface side (the lower surface 23 side in this example) of the semiconductor substrate 10 may be implanted in order from a region closer to the implantation surface.

Further, in the top view, a range where the first dopant is implanted and a range where the second dopant is implanted may be the same. The implantation ranges of all the dopants of the first conductivity type to be implanted into the buffer region 20 in the implantation process may be the same.

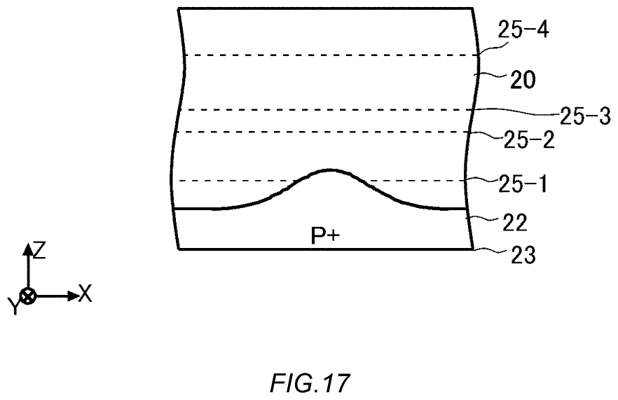

FIG. 17 illustrates a view showing a cross-sectional shape of the collector region 22 according to the comparative example. In this example, dopants are implanted into the buffer region 20 in order from a position far from the lower surface 23. In this case, for example, a dopant, such as the first dopant, having a shallow implantation position and small acceleration energy may be shielded by particles on the implantation surface. When the first dopant is locally shielded, the doping concentration peak 25-1 is locally missing in an XY plane.

When the doping concentration peak 25-1 is locally missing, the donor concentration in the region becomes low, so that the collector region 22 easily enters the region. As a result, as illustrated in FIG. 17, a portion protruding upward is generated in a part of the collector region 22. Thus, when the semiconductor device 100 is turned off, the depletion layer expanding from the lower end of the base region 14 easily reaches the collector region 22. In the transistor portion 70, the collector region 22 of the p type is formed on the lower surface 23 of the semiconductor substrate 10. Further, also in the edge termination structure portion 90 and a part of a region of the diode portion 80, the collector region 22 may be formed on the lower surface 23. In the region where the collector region 22 of the p type is formed on the lower surface 23 in this manner, when the doping concentration peak 25-1 is locally missing, the breakdown voltage decreases.

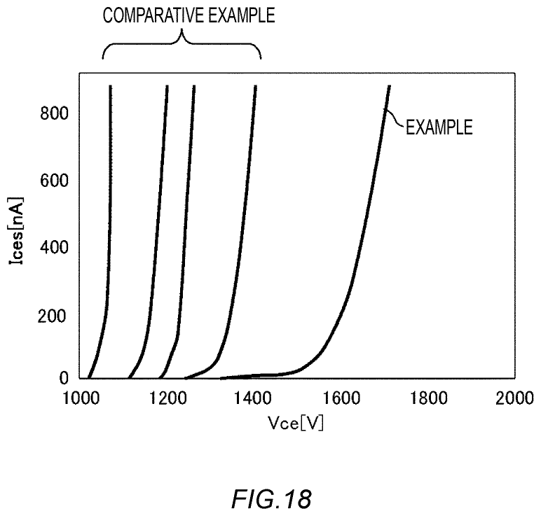

FIG. 18 illustrates a view showing a result of a breakdown voltage test of the semiconductor device. In FIG. 18, a horizontal axis represents the voltage applied between the emitter and the collector of the semiconductor device in an off state, and a vertical axis represents the current flowing between the emitter and the collector of the semiconductor device. In the semiconductor device of the comparative example described in FIG. 17, when an emitter-collector voltage Vce is 1400 V or less, a large emitter-collector current Ices flows. In contrast, in the semiconductor device 100 according to the example, even when the emitter-collector voltage Vce was approximately 1600 V, a large emitter-collector current Ices did not flow. That is, in the semiconductor device 100 according to the example, a breakdown voltage is improved compared with that of the comparative example.

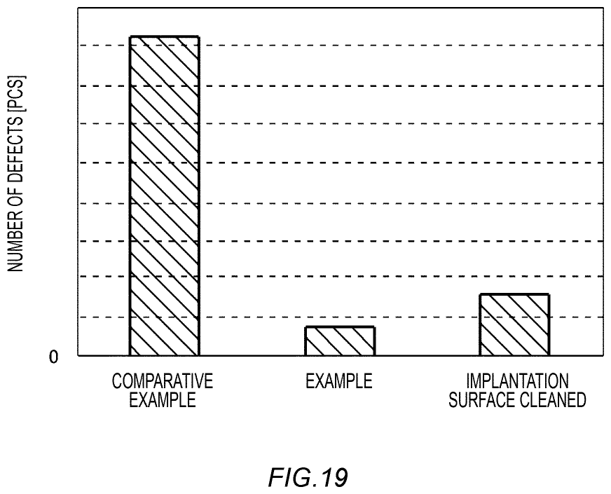

FIG. 19 illustrates a view showing a result of a breakdown voltage test of the semiconductor device. FIG. 19 shows the number of semiconductor devices determined to be defective by the breakdown voltage test. In the breakdown voltage test, a semiconductor device having a predetermined breakdown voltage or less is determined to be defective. FIG. 19 shows test results of a semiconductor device of a reference example in which an implantation surface is cleaned and each dopant is implanted, in addition to the semiconductor device 100 according to the comparative example and the example shown in FIG. 17. In the reference example, the dopant was implanted into the buffer region 20 in the same implantation order as in the comparative example, and the implantation surface was cleaned with water each time the dopant was implanted.

As illustrated in FIG. 19, according to the example, the number of defects could be significantly reduced without changing the design of each concentration distribution in the buffer region 20 as compared with the comparative example. Further, the number of defects can be reduced in the example as compared with the reference example in which the implantation surface is cleaned. As described above, in the semiconductor device 100 in which the collector region 22 of the p type is formed on the lower surface 23, the number of defects of the breakdown voltage can be significantly reduced.

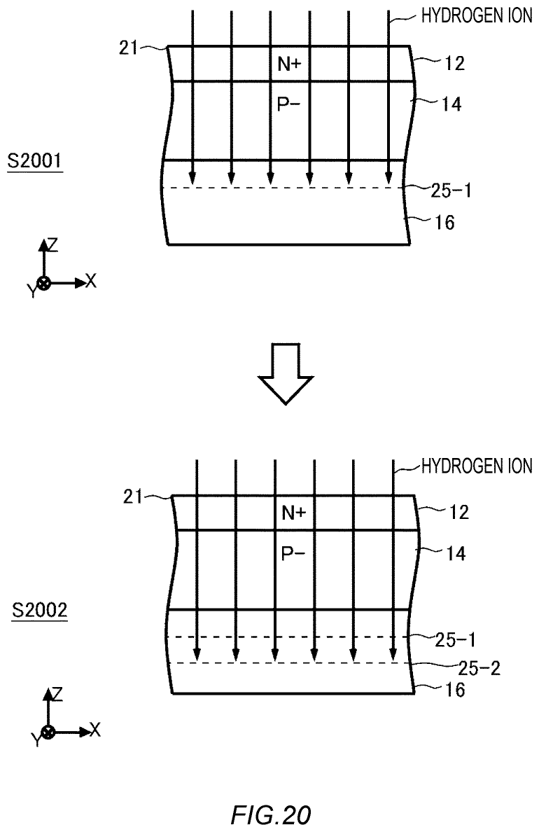

FIG. 20 illustrates a view showing another example of the semiconductor device 100. In the example described in FIGS. 14 to 16, an example in which the buffer region 20 has the plurality of doping concentration peaks 25 has been described. In the semiconductor device 100 of this example, the accumulation region 16 has a plurality of doping concentration peaks 25. In FIG. 20, a process of implanting a dopant into the accumulation region 16 will be described. The buffer region 20 may or may not have a plurality of doping concentration peaks 25 formed in processes similar to those of the example of FIGS. 14 to 16.

In the process of implanting the dopant into the accumulation region 16, each dopant may be implanted in an order similar to that of the process of implanting the dopant into the buffer region 20 described in FIGS. 14 to 16. Note that this example is different from the example of FIGS. 14 to 16 in that the implantation surface is the upper surface 21 and the reference position of the implantation position of each dopant is the upper surface 21. Other content may be the same as that of the example of FIGS. 14 to 16. For example, in the description of the implantation process in FIG. 16, the “buffer region 20” may be replaced with the “accumulation region 16”, and the “lower surface 23” may be replaced with the “upper surface 21”.

In the example of FIG. 20, first, the first dopant of the N type is implanted into the first implantation position from the implantation surface of the semiconductor substrate 10 (S2001). In this example, the implantation surface is the upper surface 21. Further, the first implantation position is a position away from the upper surface 21 by the distance Zd1 or Zh1. Further, the first dopant is, for example, a hydrogen ion or a phosphorous ion.

After the first dopant is implanted, the second dopant of the N type is implanted from the implantation surface (the upper surface 21 in this example) of the semiconductor substrate 10 into the second implantation position having a larger distance from the implantation surface than the first implantation position (S2002). In this example, the second implantation position is a position away from the upper surface 21 by the distance Zd2 or Zh2. In this example, a first depth position (first implantation position) into which the first dopant is implanted and a second depth position (second implantation position) into which the second dopant is implanted are arranged in the accumulation region 16. Further, the second dopant is, for example, a hydrogen ion or a phosphorous ion. The second dopant may be the same element as the first dopant. For example, both the first dopant and the second dopant are hydrogen ions. In another example, one of the first dopant and the second dopant may be a phosphorous ion, and the other may be a hydrogen ion.

In the example of FIG. 20, the accumulation region 16 has two doping concentration peaks 25, but it is sufficient if the number of the doping concentration peaks 25 may be two or more. According to this example, after the first dopant is implanted, the second dopant is implanted at a deeper position. Thus, even when the foreign matter adheres to the implantation surface in the process of implanting the second dopant (S2002), the implantation of the first dopant is not affected. Thus, the implantation of the first dopant having a relatively small acceleration energy can be performed precisely.

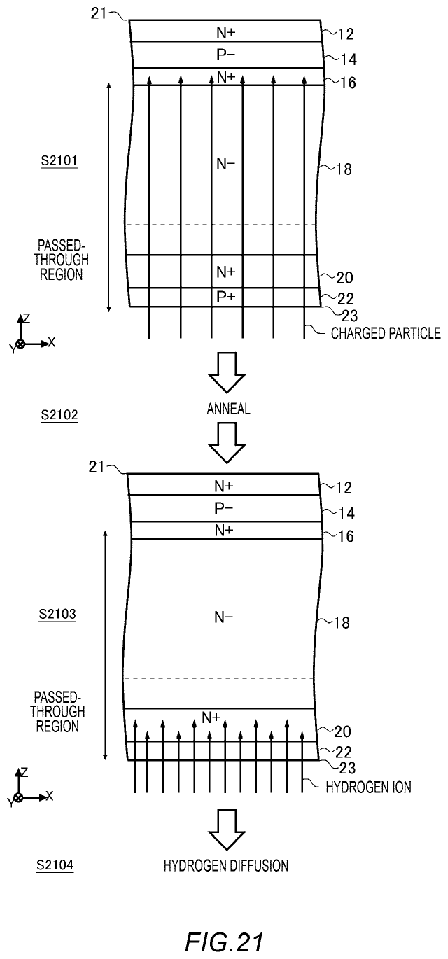

FIG. 21 illustrates a view showing another example of the manufacturing process of the semiconductor device 100. In this example, the passed-through region forming process S2101 is executed before the implantation process described with reference to FIG. 16. Further, any dopant implanted into the buffer region 20 is hydrogen ions. At least one of the first dopant and the second dopant having a relatively high doping concentration may be hydrogen ions. Further, the other dopant may be hydrogen ions.

In the passed-through region forming process S2101, charged particles are implanted from the lower surface 23. The charged particles are hydrogen ions, helium ions, electron beams, or the like. The range of the charged particles is half or more of the thickness of the semiconductor substrate 10. The range of the charged particles may be larger than the thickness of the semiconductor substrate 10. The region of the semiconductor substrate 10 through which the charged particles have passed is referred to as a passed-through region. The passed-through region may include half or more of the drift region 18 in the depth direction, or may include the whole.

In the passed-through region through which the charged particles have passed in the semiconductor substrate 10, the lattice defects mainly composed of vacancies such as monatomic vacancies (V) and diatomic vacancies or divacancies (VV) are formed by the charged particles passing therethrough. Atoms adjacent to the vacancies have dangling bonds. The lattice defects also include interstitial atoms, dislocations, and the like, and may include donors and acceptors in a broad sense. However, in the present specification, the lattice defects mainly composed of vacancies may be referred to as vacancy-type lattice defects, vacancy-type defects, or simply lattice defects. In the present specification, the concentration of lattice defects mainly composed of vacancies may be referred to as a vacancy concentration. Further, since many lattice defects are formed due to the implantation of the charged particles into the semiconductor substrate 10, the crystallinity of the semiconductor substrate 10 may be strongly disturbed. In the present specification, this disturbance of crystallinity may be referred to as disorder.

After the passed-through region forming process S2101, an implantation process S2103 is performed. An annealing process S2102 of annealing the semiconductor substrate 10 may be performed between the passed-through region forming process S2101 and the implantation process S2103.

The implantation process S2103 includes processes S1601 to S1604 described in FIG. 16. As described above, in the implantation process S2103, hydrogen ions are implanted into at least one depth position of the buffer region 20. Thus, the buffer region 20 contains hydrogen.

After the implantation process S2103, a hydrogen diffusion process S2104 is performed. In the hydrogen diffusion process S2104, hydrogen in the buffer region 20 is diffused into the passed-through region by annealing the semiconductor substrate 10. The annealing temperature in hydrogen diffusion process S2104 may be equal to or lower than the annealing temperature in the annealing process S2102.

Oxygen is contained In the entire semiconductor substrate 10. The oxygen is introduced intentionally or unintentionally during manufacturing a semiconductor ingot. In the semiconductor substrate 10, hydrogen (H), vacancies (V), and oxygen (O) are combined to form a VOH defect. Further, by diffusing hydrogen after forming the passed-through region, lattice defects in the passed-through region are combined to hydrogen, and formation of the VOH defect is promoted. The VOH defect functions as a donor that supplies electrons. In the present specification, the VOH defect may be referred to simply as a hydrogen donor.

In the semiconductor substrate 10 of this example, the hydrogen donor is formed in a hydrogen ion passed-through region. The hydrogen donor in the passed-through region is formed when hydrogen terminates the dangling bond of vacancy-type lattice defects formed in the passed-through region and is further combined to oxygen. Therefore, the doping concentration distribution of the hydrogen donor in the passed-through region may follow a vacancy concentration distribution. The hydrogen chemical concentration in the passed-through region may be 10 times or more the vacancy concentration formed in the passed-through region, or may be 100 times or more. The hydrogen in the passed-through region may be hydrogen remaining after the passage of hydrogen ions, or may be hydrogen diffused from a hydrogen supply source described below. The doping concentration of the hydrogen donor is lower than the chemical concentration of hydrogen. When the ratio of the doping concentration of the hydrogen donor to the chemical concentration of hydrogen is defined as an activation ratio, the activation ratio may be a value of 0.1% to 30%. In this example, the activation ratio is 1% to 5%.

By forming a hydrogen donor in the passed-through region of the semiconductor substrate 10, the donor concentration in the passed-through region can be made higher than the bulk donor concentration. Normally, it is necessary to prepare the semiconductor substrate 10 having a predetermined bulk donor concentration in correspondence to characteristics of an element to be formed on the semiconductor substrate 10, particularly a rated voltage or a breakdown voltage. In this case, as described in FIG. 4A, the doping concentration of the drift region 18 is substantially equal to the bulk donor concentration. In contrast, according to the semiconductor device 100 illustrated in FIG. 21, the donor concentration of the semiconductor substrate 10 can be adjusted by controlling the dose amount of the charged particles or the hydrogen ions. Thus, the semiconductor device 100 having the drift region 18 with a predetermined doping concentration can be manufactured using a semiconductor substrate with a bulk donor concentration that does not correspond to the characteristics and the like of the element. The variation in the bulk donor concentration at the time of manufacturing the semiconductor substrate 10 is relatively large, but the dose amount of the hydrogen ions can be controlled with relatively high precision. Thus, the concentration of lattice defects generated by implanting hydrogen ions can also be controlled with high precision, and the donor concentration of the passed-through region can be controlled with high precision.

In the example of FIG. 21, the implantation process S2103 is performed after the passed-through region forming process S2101. In another example, the passed-through region forming process S2101 may be performed between the implantation process S2103 and the hydrogen diffusion process S2104.

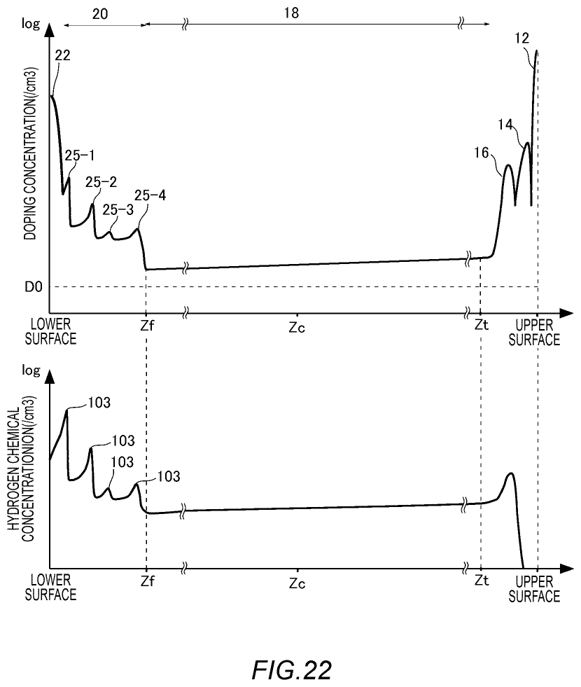

FIG. 22 illustrates a view showing an example of the doping concentration distribution and the hydrogen chemical concentration distribution of the semiconductor device 100 shown in FIG. 21. FIG. 22 shows a concentration distribution at a position corresponding to the line F-F shown in FIG. 3. In this example, in the passed-through region forming process S2101, charged particles are implanted into the semiconductor substrate 10 in a range larger than the thickness of the semiconductor substrate 10. That is, most of the charged particles passes through the semiconductor substrate 10.

As described above, lattice defects are formed in a region through which the charged particles pass in the semiconductor substrate 10. In this example, the entire semiconductor substrate 10 is a passed-through region. Then, the hydrogen diffused from the buffer region 20 in the hydrogen diffusion process S2104 is combined to lattice defects to form VOH defects. Thus, the doping concentration in the passed-through region is higher than a bulk donor concentration D0.

Further, the hydrogen chemical concentration may monotonically decrease from the buffer region 20 toward the upper surface 21, may be flat, or may monotonically increase. For example, when hydrogen ions are implanted as the charged particles in the passed-through region forming process S2101, the hydrogen chemical concentration may monotonically increase from the buffer region 20 toward the upper surface 21. The doping concentration may monotonically decrease from the buffer region 20 toward the upper surface 21, may be flat, or may monotonically increase.

### Third Example

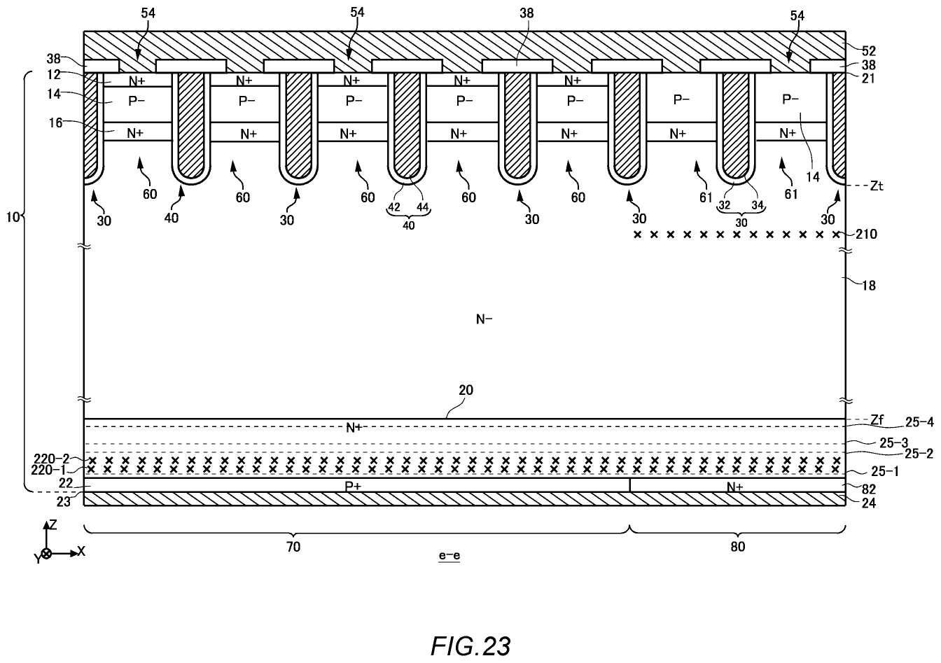

FIG. 23 illustrates a view showing another example of the cross section e-e. The semiconductor device 100 of this example is different from each example described in FIGS. 1 to 22 in that the buffer region 20 has a plurality of doping concentration peaks 25 and a plurality of lower-surface-side lifetime killers 220. The structure and the forming method of the plurality of doping concentration peaks 25 are the same as those in the second example described in FIGS. 14 to 22. Further, the structure and the forming method of the plurality of lower-surface-side lifetime killers 220 are similar to those of the first example described in FIGS. 1 to 13. The buffer region 20 has a plurality of helium chemical concentration peaks 221 corresponding to the plurality of lower-surface-side lifetime killers 220, as in the first example described in FIGS. 1 to 13. The structure other than the buffer region 20 is the same as any of the examples described in FIGS. 1 to 22.

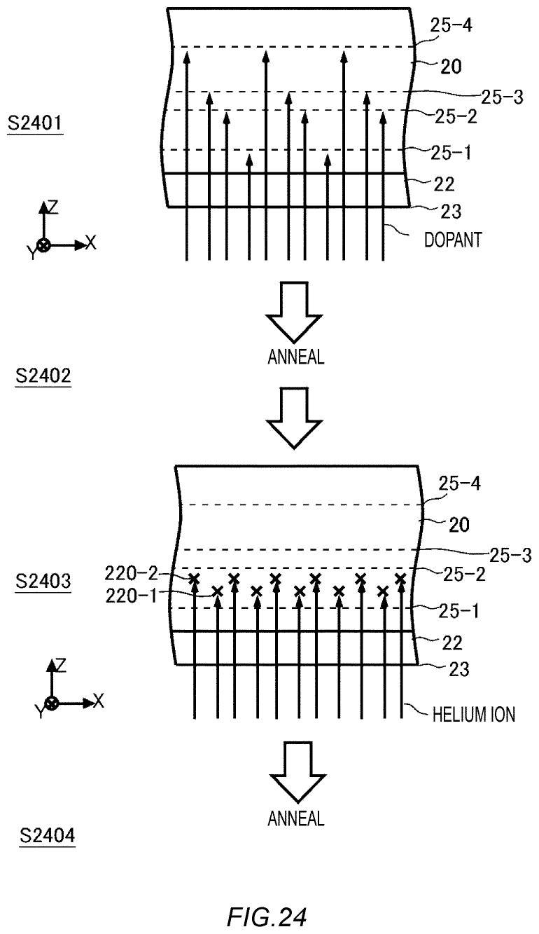

FIG. 24 illustrates a view showing an example of a method of forming the buffer region 20 shown in FIG. 23. In this example, first, in the implantation process S2401, dopants such as hydrogen ions are implanted into a plurality of depth positions of the buffer region 20. The implantation process S2401 includes processes S1601 to S1604 described in FIG. 16.

Next, in a first annealing process S2402, the semiconductor substrate 10 is annealed. Accordingly, the plurality of doping concentration peaks 25 can be formed in the buffer region 20.

Next, in a helium implantation process S2403, helium ions are implanted into different depth positions of the buffer region 20 from the lower surface 23. In the helium implantation process S2403, helium ions may be implanted in order from a depth position close to the lower surface 23. In another example, helium ions may be implanted in a different order. In the helium implantation process S2403, helium ions also may be implanted in order from a depth position having a long distance from the lower surface 23. Even when the helium chemical concentration peak 221 is locally missing, the protrusion of the collector region 22 as shown in FIG. 17 is not formed. Further, by performing the implantation process S2401 before the helium implantation process S2403, it is possible to prevent the dopant in the implantation process S2401 from being shielded by the foreign matter adhering to the implantation surface in the helium implantation process S2403.

A second annealing process S2404 of annealing the semiconductor substrate 10 may be performed after the helium implantation process S2403. Accordingly, excessive lattice defects or the like generated in the helium implantation process S2403 can be terminated with hydrogen. The annealing temperature in the second annealing process S2404 may be lower than the annealing temperature in the first annealing process S2402.

In this example, the helium implantation process S2403 is performed after the implantation process S2401. In another example, the implantation process S2401 may be performed after the helium implantation process S2403. An annealing process is preferably performed after each implantation process.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A manufacturing method of a semiconductor device including a semiconductor substrate, wherein
the semiconductor substrate includes a drift region of a first conductivity type and a buffer region provided between the drift region and an implantation surface of the semiconductor substrate and having a higher doping concentration than the drift region, the manufacturing method comprising
implanting a first dopant of a first conductivity type from the implantation surface of the semiconductor substrate into a first implantation position of the buffer region and implanting a second dopant of the first conductivity type from the implantation surface of the semiconductor substrate into a second implantation position of the buffer region having a larger distance from the implantation surface than the first implantation position after implanting the first dopant.

2. A manufacturing method of a semiconductor device including a semiconductor substrate, wherein
the semiconductor substrate includes a drift region of a first conductivity type, a base region of a second conductivity type provided between the drift region and an implantation surface of the semiconductor substrate, and an accumulation region provided between the base region and the drift region and having a higher doping concentration than the drift region, the manufacturing method comprising
implanting a first dopant of a first conductivity type from the implantation surface of the semiconductor substrate into a first implantation position of the accumulation region and implanting a second dopant of the first conductivity type from the implantation surface of the semiconductor substrate into a second implantation position of the accumulation region having a larger distance from the implantation surface than the first implantation position after implanting the first dopant.

3. The manufacturing method of a semiconductor device according to claim 1, wherein the first dopant and the second dopant are dopants of a same element.

4. The manufacturing method of a semiconductor device according to claim 3, wherein the first dopant and the second dopant are hydrogen ions.

5. The manufacturing method of a semiconductor device according to claim 1, wherein one of the first dopant and the second dopant is a phosphorous ion, and an other is a hydrogen ion.

6. The manufacturing method of a semiconductor device according to claim 1, wherein
in the implanting, three or more dopants of the first conductivity type including the first dopant and the second dopant are implanted from the implantation surface of the semiconductor substrate into implantation positions having depths different from each other in the buffer region, and
in the implanting, among three or more of the dopants, a dopant to be implanted into the implantation position closest to the implantation surface of the semiconductor substrate is implanted initially.

7. The manufacturing method of a semiconductor device according to claim 2, wherein
in the implanting, three or more dopants of the first conductivity type including the first dopant and the second dopant are implanted from the implantation surface of the semiconductor substrate into implantation positions having depths different from each other in the accumulation region, and
in the implanting, among three or more of the dopants,
a dopant to be implanted into the implantation position closest to the implantation surface of the semiconductor substrate is implanted initially.

8. The manufacturing method of a semiconductor device according to claim 7, wherein in the implanting, among three or more of the dopants, a dopant to be implanted into the implantation position farthest from the implantation surface of the semiconductor substrate is implanted finally.

9. The manufacturing method of a semiconductor device according to claim 8, wherein in the implanting, the dopant is implanted in order from the implantation position close to the implantation surface of the semiconductor substrate.

10. The manufacturing method of a semiconductor device according to claim 7, wherein a distance between the implantation position, which is farthest from the implantation surface of the semiconductor substrate among the implantation positions of three or more of the dopants, and the implantation surface of the semiconductor substrate is half or less of a thickness of the semiconductor substrate.

11. The manufacturing method of a semiconductor device according to claim 1, wherein
the semiconductor substrate includes a collector region of a second conductivity type provided between the buffer region and the implantation surface, and
the collector region is formed after the implanting.

12. The manufacturing method of a semiconductor device according to claim 1, further comprising implanting helium by implanting helium ions into the buffer region.

13. The manufacturing method of a semiconductor device according to claim 12, wherein in the implanting helium, the helium ions are implanted into different depth positions of the buffer region.

14. The manufacturing method of a semiconductor device according to claim 12, further comprising:
first annealing by annealing the semiconductor substrate after the implanting and before the implanting helium; and
second annealing by annealing the semiconductor substrate after the implanting helium.

15. The manufacturing method of a semiconductor device according to claim 1, wherein in a top view, a range where the first dopant is implanted and a range where the second dopant is implanted are same.

16. The manufacturing method of a semiconductor device according to claim 1, wherein
at least one of the first dopant and the second dopant is a hydrogen ion, the manufacturing method further comprising:
forming a passed-through region by implanting charged particles from the implantation surface in a range of half or more of a thickness of the semiconductor substrate; and
diffusing hydrogen by annealing the semiconductor substrate after the forming a passed-through region and the implanting.

17. The manufacturing method of a semiconductor device according to claim 16, wherein the forming a passed-through region is performed before the implanting.

18. The manufacturing method of a semiconductor device according to claim 16, wherein a range of the charged particles is larger than a distance of the second implantation position with respect to the implantation surface.

19. The manufacturing method of a semiconductor device according to claim 17, further comprising annealing the semiconductor substrate after the forming a passed-through region and before the implanting.

20. A semiconductor device comprising:
a semiconductor substrate having an upper surface and a lower surface;
a drift region of a first conductivity type provided in the semiconductor substrate; and
a buffer region of the first conductivity type provided between the drift region and the lower surface, wherein
the buffer region includes, in an adjacent region in contact with the drift region, a plurality of hydrogen chemical concentration peaks in which a hydrogen chemical concentration decreases as a distance from the lower surface increases, and
a slope α of a straight line approximating a doping concentration distribution in the adjacent region is 20 (/cm) or more and 200 (/cm) or less, wherein
when a depth position of one end of the adjacent region is x1 [cm], a depth position of an other end is x2 [cm], a doping concentration at the depth position x1 is N1 [/cm³], and a doping concentration at the depth position x2 is N2 [/cm³], the slope α is given by a following equation
α=(|log₁₀(N2)−log₁₀(N1)|)/(|x2−x1|).

21. The semiconductor device according to claim 20, wherein the buffer region includes, on the lower surface side of the adjacent region, a flat portion in which a doping concentration is higher than a bulk donor concentration of the semiconductor substrate and a variation in the doping concentration is ±30% or less, a variation ratio of the doping concentration is less than a variation ratio of the hydrogen chemical concentration, and a width of a concentration peak of the doping concentration distribution corresponding to the hydrogen chemical concentration peak of a hydrogen chemical concentration distribution is larger than a width of the hydrogen chemical concentration peak of the hydrogen chemical concentration distribution.

22. The semiconductor device according to claim 21, wherein a width of the adjacent region in a depth direction from the lower surface to the upper surface is larger than a width of the flat portion in the depth direction.

23. The semiconductor device according to claim 20, wherein
the buffer region includes:
a valley portion of the hydrogen chemical concentration having a concentration of C_{Hv}, the valley portion being arranged adjacent to the hydrogen chemical concentration peak having a concentration of C_{Hp} on the upper surface side;
a doping concentration peak having a concentration of Nₚ, the doping concentration peak being arranged at a depth position corresponding to the hydrogen chemical concentration peak having a concentration of C_{Hp}; and
a valley portion of the doping concentration having a concentration of Nᵥ, the valley portion being arranged adjacent to the doping concentration peak having a concentration of Nₚ on the upper surface side, and
C_{Hv}/C_{Hp}<Nᵥ/Nₚ

24. The semiconductor device according to claim 20, wherein
the buffer region includes:
a plurality of valley portions of a hydrogen chemical concentration provided between respective peaks of the plurality of hydrogen chemical concentration peaks;
a plurality of doping concentration peaks arranged at depth positions corresponding to the plurality of hydrogen chemical concentration peaks; and
a plurality of valley portions of a doping concentration provided between respective peaks of the plurality of doping concentration peaks,
an envelope connecting the plurality of hydrogen chemical concentration peaks has a first ratio to an envelope connecting the plurality of valley portions of the hydrogen chemical concentration,
an envelope connecting the plurality of doping concentration peaks has a second ratio to an envelope connecting the plurality of valley portions of the doping concentration, and
the first ratio is larger than the second ratio.

25. The semiconductor device according to claim 20, wherein the adjacent region occupies 30% or more of the buffer region in the depth direction.

26. The semiconductor device according to claim 21, wherein a width of the adjacent region in the depth direction is larger than a width of the flat portion in the depth direction.
